(19) United States
(12) Patent Application Publication
(10) Pub. No.: US 2024/0164129 A1
(43) Pub. Date: May 16, 2024

(54) ELECTROLUMINESCENT DEVICE AND DISPLAY DEVICE INCLUDING THE SAME

(71) Applicant: SAMSUNG ELECTRONICS CO., LTD., Suwon-si (KR)

(72) Inventors: Kwang Hee KIM, Suwon-si (KR); Yuho WON, Suwon-si (KR); Jae Yong LEE, Suwon-si (KR); Oul CHO, Suwon-si (KR); Ha Il KWON, Suwon-si (KR); Ju Hyun KIM, Suwon-si (KR); Won Sik YOON, Suwon-si (KR); Taehyung KIM, Suwon-si (KR)

(21) Appl. No.: 18/508,605

(22) Filed: Nov. 14, 2023

(30) Foreign Application Priority Data
Nov. 14, 2022 (KR) 10-2022-0151863

(51) Int. Cl. H10K 50/115; C09K 11/02; C09K 11/88

(52) U.S. Cl. CPC H10K 50/115; C09K 11/02; C09K 11/883; H10K 2101/30

(57) ABSTRACT

An electroluminescent device includes a first electrode and a second electrode facing each other; a quantum dot layer disposed between the first electrode and the second electrode and including a plurality of quantum dots; optionally, an electron transport layer between the quantum dot layer and the second electrode; wherein the quantum dot layer is configured to emit first light. The electroluminescent device further includes a first layer including an inorganic nanoparticle between the quantum dot layer and the first electrode, and inorganic nanoparticle includes a metal chalcogenide including a Group II metal and a chalcogen element. The inorganic nanoparticle has a size of greater than or equal to about 0.5 nanometers and less than or equal to about 30 nanometers.

### CROSS-REFERENCE TO RELATED APPLICATION

This application claims priority to Korean Patent Application No. 10-2022-0151863 filed in the Korean Intellectual Property Office on Nov. 14, 2022, and all the benefits accruing therefrom under 35 U.S.C. § 119, the entire content of which is herein incorporated by reference.

### BACKGROUND

### 1. Field

The present disclosure relates to an electroluminescent device and a device including the same.

### 2. Description of the Related Art

A semiconductor nanoparticle (e.g., including a semiconductor nanocrystal) has a dimension of nanometer size and may emit light. Moreover, a semiconductor nanoparticle including a semiconductor nanocrystal may exhibit a quantum confinement effect. For example, light emission from the semiconductor nanoparticle may occur when an electron in an excited state resulting from light excitation or an applied voltage transits from a conduction band to a valence band. The semiconductor nanoparticle may be configured to emit light of a desired wavelength region by adjusting a size and/or composition of the semiconductor nanoparticle. Nanoparticles may be used in a luminescent device (e.g., electroluminescent device) and a display device including the electroluminescent device.

### SUMMARY

Embodiments provide a luminescent device that emits light, e.g., by applying a voltage to a layer of the device that includes a semiconductor nanoparticle, e.g., a quantum dot.

Embodiments provide a display device (e.g., a QD-LED display device) including a layer that includes a semiconductor nanoparticle, e.g., a quantum dot, as a light emitting material in one or more pixels.

Embodiments provide a method of manufacturing the aforementioned luminescent device.

In an embodiment, an electroluminescent device includes:
a first electrode and a second electrode; a quantum dot layer between the first electrode and the second electrode; and optionally, an electron transport layer between the quantum dot layer and the second electrode;
wherein the quantum dot layer includes a quantum dot (e.g., a plurality of quantum dots) and is configured to emit a first light, and the electroluminescent device further includes a first layer including an inorganic nanoparticle (e.g., a plurality of inorganic nanoparticles), the first layer disposed between the quantum dot layer and the first electrode,
wherein the inorganic nanoparticle includes a metal chalcogenide including a Group II metal (e.g., a Group IIA metal or a Group IIB metal) and a chalcogen element (sulfur, selenium, tellurium, or a combination thereof), and
the inorganic nanoparticle has a size (e.g., an average size of a plurality of inorganic nanoparticles) of greater than or equal to about 0.5 nanometers (nm) and less than or equal to about 30 nm.

The electronic transport layer that may be present in the device may include a zinc oxide nanoparticle. The zinc oxide nanoparticle may further include an alkali metal, an alkaline earth metal, Zr, W, Li, Ti, Y, Al, gallium, indium, tin (Sn), cobalt (Co), vanadium (V), or a combination thereof.

The quantum dot may include a Group II-VI compound, a Group III-V compound, a Group IV-VI compound, a Group IV element or compound, a Group II-III-VI compound, a Group I-III-VI compound, a Group I-II-IV-VI compound, or a combination thereof.

The first light may represent a red light spectrum, a green light spectrum, a blue light spectrum, or a combination thereof. The first light may have a full width at half maximum (FWHM) of the emission peak of less than or equal to about 55 nm, or less than or equal to about 45 nm. The first light may have a full width at half maximum of an emission peak of greater than or equal to about 1 nm, or greater than or equal to about 10 nm.

The quantum dot may have a core shell structure. The core shell structure may include a core including the first semiconductor nanocrystal and a shell disposed on the core. The shell may include a crystalline or amorphous inorganic material.

The first semiconductor nanocrystal may include a zinc chalcogenide, an indium phosphide, or a combination thereof.

The quantum dot layer may include or may not include the inorganic nanoparticle (e.g., of the first layer).

The Group II metal of the inorganic nanoparticle may include a metal including zinc, magnesium, calcium, barium, strontium, or a combination thereof. The chalcogen element may include selenium, sulfur, tellurium, or a combination thereof.

The metal chalcogenide may include a magnesium sulfide, a magnesium selenide, a magnesium sulfide selenide, a zinc magnesium selenide, a zinc magnesium sulfide, a zinc sulfide, a zinc selenide sulfide, a barium sulfide, a barium selenide, a barium sulfide selenide, a calcium sulfide, a calcium selenide, a calcium selenide sulfide, or a combination thereof.

The metal chalcogenide may include two or more compounds.

The inorganic nanoparticle may have a size (e.g., an average size) that is greater than or equal to about 1 nm, greater than or equal to about 2 nm, or greater than or equal to about 2.5 nm. The inorganic nanoparticle may have an (average) size of less than about 30 nm, less than or equal to about 25 nm, less than or equal to about 20 nm, less than or equal to about 15 nm, less than or equal to about 7 nm, or less than or equal to about 6.5 nm.

The inorganic nanoparticle may have an (average) size in a range of less than or equal to about 10 nm.

A (bulk) bandgap energy of the metal chalcogenide or the inorganic nanoparticle including the metal chalcogenide (hereinafter, can be referred to as “the metal chalcogenide”) may be greater than or equal to about 3.0 eV, greater than or equal to about 3.4 eV, greater than or equal to about 3.2 eV, or greater than or equal to about 3.5 eV. The (bulk) bandgap energy of the metal chalcogenide may be less than or equal to about 6 eV, less than or equal to about 5.5 eV, or less than or equal to about 3.8 eV.

The first layer may have a thickness of greater than or equal to about 2 nm, or greater than or equal to about 4 nm. The first layer may have a thickness of less than or equal to about 50 nm, less than or equal to about 35 nm, or less than or equal to about 20 nm.

The quantum dot layer may have a thickness of greater than or equal to about 5 nm, or greater than or equal to about 7 nm. The quantum dot layer may have a thickness of less than or equal to about 80 nm, or less than or equal to about 50 nm. A HOMO energy level of the metal chalcogenide may be shallower (e.g. less) than a HOMO energy level of the quantum dot or the quantum dot layer including the quantum dot (hereinafter, can be referred to as a quantum dot layer).

A difference between a HOMO energy level of the metal chalcogenide and a HOMO energy level of the quantum dot layer may be greater than or equal to about 0.001 eV, greater than or equal to about 0.005 eV, or greater than or equal to about 0.01 eV, and less than or equal to about 0.3 eV. The difference between a HOMO energy level of the metal chalcogenide and a HOMO energy level of the quantum dot layer may be less than or equal to about 0.25 eV, or less than or equal to about 0.1 eV.

The first layer or the inorganic nanoparticle may further include an organic moiety (e.g., an organic group), and a mole ratio of carbon to the Group II metal in the first layer may be greater than or equal to about 0.001:1, greater than or equal to about 0.01:1, greater than or equal to about 0.05:1, greater than or equal to about 0.1:1, or greater than or equal to about 0.2:1, and may be less than or equal to about 1:1, or less than or equal to about 0.5:1.

In the first layer, the inorganic nanoparticle may further include an organic ligand (e.g., a bifunctional organic ligand) for example, bound to a surface of the inorganic nanoparticle.

The organic ligand compound may include a compound represented by Chemical Formula 1:

A-L-B Chemical Formula 1
L is a single bond, a C1 to C50 aliphatic hydrocarbon group (e.g., a divalent C1 to C50 aliphatic hydrocarbon group), a C6 to C50 aromatic hydrocarbon group (e.g., a divalent C6 to C50 aromatic hydrocarbon group), or a combination thereof,
A and B are each independently a thiol group (—SH), a carboxyl group (—COOH), a hydroxy group (—OH), an amine group (—NHR, or —NH₂ wherein R is an C1 to C50 alkyl group), a phosphonic acid group (—PO₃R₂, wherein R is independently hydrogen or C1 to C50 alkyl group provided that at least one R is hydrogen), a phosphoric acid group —OP(O)(OR)₂ wherein R is independently hydrogen or a C1 to C50 alkyl group, provided that at least one R is hydrogen), a phosphinic acid group (—PO₂R₂, wherein R independently is hydrogen or a C1 to C50 alkyl group provided that at least one R is hydrogen), or a moiety derived from the foregoing group (for example, a thiolate, a carboxylate, an alkoxylate, or the like).

Either A or B may have a group (for example, a thiolate, a carboxylate, an alkoxylate, or the like) that can interact with a surface of the inorganic nanoparticle.

The inorganic nanoparticle may be configured to be dispersed in water or a water-miscible organic solvent.

The inorganic nanoparticle may be dispersed in a water-miscible organic solvent, and a particle diameter measured by a dynamic light scattering analysis (e.g., a DLS analysis) may be greater than or equal to about 1 nm and less than or equal to about 1000 nm, or less than or equal to about 100 nm, or less than or equal to about 30 nm, or about 5 nm to about 10 nm.

The organic ligand may include a diacid compound, a mercapto carboxylic acid compound, a mercapto amine compound, a mercapto phosphonic acid compound, a mercaptophosphoric acid compound, a mercaptophosphinic acid compound, a hydroxy carboxylic acid compound, a hydroxy amine compound, a hydroxy phosphonic acid compound, a hydroxyphosphoric acid compound, a hydroxyphosphinic acid compound, or a combination thereof (e.g., two or more compounds thereof).

The organic ligand may include a mercaptopropionic acid compound, a thioglycolic acid compound, a mercaptobutanoic acid compound, a mercaptopentanoic acid compound, a mercaptohexanoic acid compound, a mercaptomethanol compound, a mercaptoethanol compound, a mercaptopropanol compound, or a combination thereof (e.g., a two or more compounds thereof).

The electroluminescent device may include a hole auxiliary layer between the first electrode and the first layer.

The hole auxiliary layer may include a hole transport layer including a hole transporting organic compound, a hole injection layer, or a combination thereof.

The hole transporting organic compound may include, for example, a compound (e.g., a non-polymeric compound such as a molecular compound or a (co)polymeric compound) including (for example, in a backbone of the compound) a substituted or unsubstituted fluorenyl moiety, a substituted or unsubstituted diphenylamine moiety, a (twisted) triphenylamine moiety, or a combination thereof; or a combination of the compounds thereof. In an embodiment, the hole transporting organic compound may include a fluorene compound substituted with a substituted or unsubstituted aryl amine group (e.g., a triphenyl amine group), a substituted or unsubstituted C1 to C30 or C4-C28 alkyl group, a carbazole group, or a combination thereof. The hole transporting organic compound may include a fluorene aryl amine compound with a substituted or unsubstituted C1 to C30 or C4-C28 alkyl group, a fluorene aryl amine compound with a substituted or unsubstituted carbazole group, a fluorene carbazole compound, or a combination thereof.

A LUMO level of the metal chalcogenide may be less (shallower) than a LUMO level of the hole transporting organic compound or the hole transport layer including the hole transporting organic compound (hereinafter, can be referred to as the hole transport layer). The LUMO level of the hole transport layer may be less (shallower) than the LUMO level of the quantum dot layer. The LUMO level of the metal chalcogenide may be less (shallower) than the LUMO level of the quantum dot layer.

A difference between the LUMO level of the hole transport layer and the LUMO level of the quantum dot layer may be greater than or equal to about 0.5 eV, or greater than or equal to about 0.8 eV and less than or equal to about 2 eV, or less than or equal to about 1 eV. A difference between the LUMO level of the metal chalcogenide and the LUMO level of the hole transport layer may be greater than or equal to about 0.1 eV, or greater than or equal to about 0.2 eV and less than or equal to about 1 eV, less than or equal to about 0.7 eV, less than or equal to about 0.68 eV, or less than or equal to about 0.5 eV.

A difference between the LUMO level of the metal chalcogenide and the LUMO level of the quantum dot layer may be greater than or equal to about 0.3 eV, greater than or equal to about 0.5 eV, greater than or equal to about 0.7 eV, greater than or equal to about 0.9 eV, or greater than or equal to about 0.95 eV. The difference between the LUMO level of the metal chalcogenide and the LUMO level of the quantum dot layer may be less than or equal to about 1.5 eV, less than or equal to about 1.2 eV, or less than or equal to about 1 eV.

A bulk bandgap energy of the metal chalcogenide may be greater than a bandgap energy of the hole transporting (organic) layer.

A bulk bandgap energy of the metal chalcogenide may be greater than a bandgap energy of the quantum dot layer.

A HOMO level of the metal chalcogenide may be larger (deeper) than a HOMO level of the hole transporting (organic) layer. A HOMO level of the hole transport layer may be smaller (shallower) than a HOMO level of the quantum dot layer.

A difference between the HOMO energy level of the metal chalcogenide and the HOMO energy level of the hole transport layer may be greater than or equal to about 0.01 eV, and less than or equal to about 2 eV, less than or equal to about 1 eV, less than or equal to about 0.8 eV, or less than or equal to about 0.5 eV. The difference between the HOMO energy level of the metal chalcogenide and the HOMO energy level of the hole transport layer may be greater than or equal to about 0.05 eV, or greater than or equal to about 0.09 eV, and less than or equal to about 0.3 eV, less than or equal to about 0.25 eV, or less than or equal to about 0.1 eV.

The electroluminescent device may further include a hole injection layer between the first electrode and the hole transport layer.

The hole injection layer may include the hole injecting compound, a hole transporting inorganic material, or a combination thereof.

The hole auxiliary layer (e.g., the hole transport layer and/or the hole injection layer) may each independently include poly(9,9-dioctyl-fluorene-co-N-(4)-butylphenyl)-diphenylamine) (TFB), polyarylamine, poly(N-vinylcarbazole) (PVK), poly(3,4-ethylenedioxythiophene) (PEDOT), poly(3,4-ethylenedioxythiophene) polystyrene sulfonate (PEDOT:PSS), polyaniline, polypyrrole, N,N,N′,N′-tetrakis(4-methoxyphenyl)-benzidine (TPD), 4,4′-bis[N-(1-naphthyl)-N-phenyl-amino]biphenyl (alpha-NPD), m-MTDATA (4,4′,4″-Tris[phenyl(m-tolyl)amino]triphenylamine), 4,4′,4″-tris(N-carbazolyl)-triphenylamine (TCTA), 1,1-bis[(di-4-tolylamino)phenyl]cyclohexane (TAPC), a p-type metal oxide (e.g., NiO, WO₃, MoO₃, etc.), a carbon-based material such as graphene oxide, a perovskite thin film, or a combination thereof.

The perovskite thin film may include a crystalline perovskite compound (e.g., a perovskite based on an alkali metal transition metal halide, such as cesium lead chloride, or an alkaline earth metal transition metal chalcogenide).

The electroluminescent device may be configured to emit blue light. The first light may be blue light.

The electroluminescent device may have a maximum luminance of greater than or equal to about 50,000 candela per square meter (cd/m² or nit) or greater than or equal to about 100,000 nits. The electroluminescent device may have a maximum luminance of less than or equal to about 3,000,000 nits.

The electroluminescent device may have a maximum external quantum efficiency of greater than or equal to about 11%. The electroluminescent device may have a maximum external quantum efficiency of less than or equal to about 40%.

The electroluminescent device may have a T90 of greater than or equal to about 4 hours, greater than or equal to about 7 hours, or greater than or equal to about 9 hours when the device is driven at 650 nits.

In an embodiment, a display device includes the electroluminescent device.

In an embodiment, an electronic device includes the aforementioned electroluminescent device.

The display device or the electronic device may include (may be) a portable terminal device, a monitor, a notebook computer, a television, an electric sign board, a camera, or an electronic component (for example, for an electric vehicle).

According to embodiments, an electroluminescent device is provided that can achieve increased life-span while exhibiting improved electroluminescent properties (e.g., device efficiency and luminance).

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1A is a schematic cross-sectional view of an electroluminescent device according to an embodiment.

FIG. 1B is a schematic cross-sectional view of an electroluminescent device according to an embodiment.

FIG. 1C is a schematic cross-sectional view of an electroluminescent device according to an embodiment.

FIGS. 2A and 2B show a schematic front view and a schematic cross-sectional view of a display device according to an embodiment.

FIG. 3A is the results of the HOMO level measurements for the inorganic nanoparticle after a ligand exchange and the quantum dot.

FIG. 3B is the results of the HOMO level measurements for the inorganic nanoparticle before a ligand exchange.

FIG. 4 is a schematic representation of a ligand exchange for an inorganic nanoparticle in an embodiment.

FIG. 5A is a cross-sectional TEM image of a stacked structure in which a layer of inorganic nanoparticles and a quantum dot layer are placed on an organic-based hole transport layer in an embodiment.

FIG. 5B is a cross-sectional TEM-EDX image of a stacked structure in an embodiment where the chalcogen element includes selenium.

FIG. 5C is a cross-sectional TEM-EDX image of a stacked structure in an embodiment where the chalcogen element includes selenium.

FIG. 5D is a cross-sectional TEM-EDX image of a stacked structure in an embodiment where the chalcogen element includes sulfur.

### DETAILED DESCRIPTION

Hereinafter, with reference to the accompanying drawings, various embodiments of the present disclosure will be described in detail so that those of ordinary skill in the art can easily carry out the present disclosure. The present disclosure may be embodied in many different forms and is not limited to the embodiments described herein.

In order to clearly explain the present disclosure, parts irrelevant to the description are omitted, and the same reference numerals are assigned to the same or similar elements throughout the specification.

The size and thickness of each constituent element as shown in the drawings are randomly indicated for better understanding and ease of description, and this disclosure is not necessarily limited to as shown. In the drawings, the thickness of layers, films, panels, regions, etc., are exaggerated for clarity. And in the drawings, for convenience of description, the thickness of some layers and regions are exaggerated.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion.

Further, in the entire specification, the term “planar” means a case in which a target part is viewed from the top, and the term “cross-sectional” means a case in which a cross-section of the target part that is cut in a vertical direction is viewed from the side.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements. “At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

As used herein, the average (value) may be mean or median. In an embodiment, the average (value) may be a mean value. As used herein, the term “peak emission wavelength” is the wavelength at which a given emission spectrum of the light reaches its maximum.

As used herein, the value of the work function or (HOMO or LUMO) energy level is expressed as an absolute value from the vacuum level. In addition, when the work function or the energy level is referred to be “deep,” “high” or “large,” the work function or the energy level has a large absolute value based on “0 eV” of the vacuum level, while when the work function or the energy level is referred to be “shallow,” “low,” or “small,” the work function or energy level has a small absolute value based on “0 eV” of the vacuum level.

In an embodiment, the HOMO energy level can be measured by photo-electron spectroscopy in air (e.g., photoelectron spectrophotometer, model name AC3 manufactured by Riken Keiki Co. Ltd.) or an Ultraviolet photoemission spectroscopy (UPS) or a UV absorption spectroscopy analysis (e.g., an optical band-gap measurement).

In a measurement involving the photoelectron spectroscopy analysis, when the photoelectron output is plotted on an X/Y axis, with horizontal axis as the UV energy applied, and the vertical axis as a standardized photoelectron yield ration, the result is a curved line rising with a specific slope of degree and the HOMO level is a value at which the base line meets a straight and extending line obtained from the dots in a region of the increasing slope. The standardized photoelectron yield ration, (Yield)ⁿ is the ratio of photoelectron yield achieved per unit of UV energy applied to the sample surface, and “n” represents the strength of the UV energy applied and the “n” value is from about 0.3 to 1 (e.g., 0.33).

In an embodiment, an (optical) bandgap energy may be obtained from a wavelength where a light absorption starts in a UV-Vis absorption spectrum or an X-intercept wavelength. For example, in case a point where an UV absorption curve starts (or an X-intercept of the UV absorption spectrum) is 330 nm, the energy bandgap is 1240/325=3.81 eV.

As used herein, when a definition is not otherwise provided, “substituted” refers to replacement of at least one hydrogen of a compound or the corresponding moiety by a substituent selected from a C1 to C30 alkyl group, a C2 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), or a phosphoric acid group (—PO₃H₂) or a salt thereof (—PO₃MH or —PO₃M₂, wherein M is an organic or inorganic cation).

Herein, the hydrocarbon group refers to a group containing carbon and hydrogen (e.g., an aliphatic group such as an alkyl, alkenyl, or alkynyl group, or an aromatic group such as an aryl group). The hydrocarbon group may be a group having a mono-valence or more formed by removal of one or more hydrogen atoms from alkane, alkene, alkyne, or arene. In an embodiment, the hydrocarbon group may consist of only carbon and hydrogen. In the hydrocarbon group, at least one methylene may be replaced by an oxide moiety, a carbonyl moiety, an ester moiety, —NH—, or a combination thereof. Unless otherwise stated to the contrary, the hydrocarbon group (alkyl, alkenyl, alkynyl, or aryl) may have 1 to 60, 2 to 32, 3 to 24 or 4 to 12 carbon atoms.

As used herein, “alkyl” refers to a linear or branched saturated monovalent hydrocarbon group (methyl, ethyl hexyl, etc.).

As used herein, “alkenyl” refers to a linear or branched monovalent hydrocarbon group having one or more carbon-carbon double bond.

As used herein, “alkynyl” refers to a linear or branched monovalent hydrocarbon group having one or more carbon-carbon triple bond.

As used herein, “aromatic group” refers to a group formed by removal of at least one hydrogen from an aromatic hydrocarbon (e.g., a phenyl, pyridyl, or naphthyl group). Accordingly, the term, “aromatic group” includes an aryl group as well as a heteroaryl group.

As used herein, “hetero” refers to one including 1 to 3 heteroatoms of N, O, S, Si, P, or a combination thereof.

As used herein, “alkoxy” means an alkyl group linked via an oxygen (i.e., alkyl-O—), such as a methoxy, ethoxy, or sec-butyloxy group.

An “amine group” may be —NRR, wherein each R group are independently hydrogen, a C1 to C12 alkyl group, a C7 to C20 alkylaryl group, a C7 to C20 arylalkyl group, or a C6 to C18 aryl group.

Herein, the description that does not contain cadmium (or other toxic heavy metal or element) may refer to a concentration of cadmium (or a corresponding heavy metal) of less than or equal to about 100 ppm, less than or equal to about 50 ppm, less than or equal to about 10 ppm, or almost zero. In an embodiment, substantially no cadmium (or other heavy metal) is present, or, if present, in an amount or impurity level below the detection limit of a given detection means.

Unless otherwise stated, numerical ranges stated herein are inclusive of any integer value within the endpoints of the sated range. In an embodiment, the upper and lower endpoints set forth for various numerical values may be independently combined to provide a range.

Unless otherwise stated, the words “substantially” or “approximately” or “about” are omitted before values in the numerical ranges specified herein.

As used herein, “substantially” or “approximately” or “about” means not only the stated value, but also the mean within an acceptable range of deviations, considering the errors associated with the corresponding measurement and the measurement of the measured value. For example, “about” can mean within ±10%, 5%, 3%, or 1% or within the experimental standard deviation of the stated value.

As used herein, a nanoparticle is a structure having a, e.g., at least one, region or characteristic dimension with a nanoscale dimension. In an embodiment, a dimension (or an average dimension) of the nanostructure is less than or equal to about 500 nanometers (nm), less than or equal to about 300 nm, less than or equal to about 250 nm, less than or equal to about 150 nm, less than or equal to about 100 nm, less than or equal to about 50 nm, or less than or equal to about 30 nm, and may be greater than about 0.1 nm or about 1 nm. In an embodiment, the nanoparticle may have any suitable shape. The nanoparticle (e.g., a semiconductor nanoparticle or a metal oxide nanoparticle) may include a nanowire, a nanorod, a nanotube, a branched nanostructure, a nano-tetrapod, a nano-tripod, a nano-bipod, a nanodot, a multi-pod type shape such as at least two pods, or the like and is not limited thereto. The nanoparticle can be, e.g., substantially crystalline, substantially monocrystalline, polycrystalline, (for example, at least partially) amorphous, or a combination thereof.

In an embodiment, a semiconductor nanoparticle such as a quantum dot may exhibit quantum confinement or exciton confinement. As used herein, the term “quantum dot” or “semiconductor nanostructure” is not limited in a shape thereof unless otherwise defined. A semiconductor nanoparticle or a quantum dot may have a size smaller than a Bohr excitation diameter for a bulk crystal material having an identical composition and may exhibit a quantum confinement effect. The semiconductor nanoparticle or the quantum dot may emit light corresponding to a bandgap energy of the semiconductor nanoparticle or the quantum dot by controlling a size of a nanocrystal acting as an emission center. The light-emitting center may or may not include a dopant. A presence of the dopant may not substantially affect the emission wavelength of the semiconductor nanocrystal, and a change in emission wavelength due to the presence of the dopant may be less than about 10 nm, less than or equal to about 7 nm, less than or equal to about 5 nm, or less than or equal to about 3 nm.

As used herein, the term “T50” is a time (hours, hr) the brightness (e.g., luminance) of a given device decreases to 50% of the initial brightness (100%) as, e.g., when, the given device is started to be driven, e.g., operated, at a predetermined initial brightness (e.g., 650 nit).

As used herein, the term “T90” is a time (hr) the brightness (e.g., luminance) of a given device decreases to 90% of the initial brightness (100%) as the given device is started to be driven at a predetermined initial brightness (e.g., 650 nit).

As used herein, the phrase “external quantum efficiency (EQE)” is a ratio of the number of photons emitted from a light emitting diode (LED) to the number of electrons passing through the device and can be a measurement as to how efficiently a given device converts electrons to photons and allows the photons to escape. The EQE may be determined by the following equation:

EQE=(efficiency of injection)×((solid-state)quantum yield)×(efficiency of extraction)

wherein the efficiency of injection is a proportion of electrons passing through the device that are injected into the active region, the quantum yield is a proportion of all electron-hole recombination in the active region that are radiative and produce photons, the efficiency of extraction is a proportion of photons generated in the active region that escape from the given device.

As used herein, a maximum EQE is a greatest value of the EQE. As used herein, a maximum luminance is the highest value of luminance for a given device.

As used herein, the phrase, quantum efficiency, may be used interchangeably with the phrase, quantum yield. In an embodiment, the quantum efficiency may be a relative quantum yield or an absolute quantum yield, for example, which can be readily measured by any suitable, e.g., commercially available, equipment. The quantum efficiency (or quantum yield) may be measured in a solution state or a solid state (in a composite). In an embodiment, “quantum yield (or quantum efficiency)” may be a ratio of photons emitted to photons absorbed, e.g., by a nanostructure or population of nanostructures. In an embodiment, the quantum efficiency may be determined by any suitable method. For example, there may be two methods for measuring the fluorescence quantum yield or efficiency: the absolute method and the relative method. The absolute method directly obtains the quantum yield by detecting all sample fluorescence through the use of an integrating sphere. In the relative method, the fluorescence intensity of a standard sample (e.g., a standard dye) may be compared with the fluorescence intensity of an unknown sample to calculate the quantum yield of the unknown sample. Coumarin 153, Coumarin 545, Rhodamine 101 inner salt, Anthracene, and Rhodamine 6G may be used as standard dye, depending on the photoluminescence (PL) wavelengths thereof, but are not limited thereto.

A bandgap energy of a semiconductor nanoparticle may vary with a size and a composition of a nanocrystal. For example, as a size of the semiconductor nanoparticle increases, the bandgap energy of the semiconductor nanoparticle may become smaller, e.g., narrower, and the semiconductor nanoparticle may emit light having an increased wavelength. A semiconductor nanocrystal may be used as a light emitting material in various fields of, e.g., such as in, a display device, an energy device, or a bio light emitting device.

A semiconductor nanoparticle based electroluminescent device (hereinafter, also referred to as a QD-LED) may emit light by applying a voltage and includes a semiconductor nanoparticle or a quantum dot as a light emitting material. In comparison to organic light emitting diode (OLED), the QD-LED may exhibit light emission with more desirable optical properties, e.g., e.g., higher purity colors (e.g., red, green, and blue) and improved color reproducibility, and therefore, may draw interest and attention as a material for a next generation display device. A method of producing the QD-LED may include a solution process, which may lower, i.e., reduce, a manufacturing cost. In addition, a semiconductor nanoparticle in the QD-LED may be based on an inorganic material, contributing to realization of increased display (light emission) stability over time. However, it is still desirable to develop a technology that can further improve device properties and life characteristics for the QD-LED.

In an embodiment of a QD-LED, holes and electrons provided from electrodes (e.g., an anode and a cathode) and moving through several common layers may combine within a quantum dot layer (EML, emitting layer, QD quantum dot layer) to form an exciton, which upon relaxation may emit light. In an embodiment of the QD-LED, a common layer may be designed between the quantum dot layer and the electrode so that holes and electrons can be transported to the light emitting layer and effectively recombine when voltage is applied.

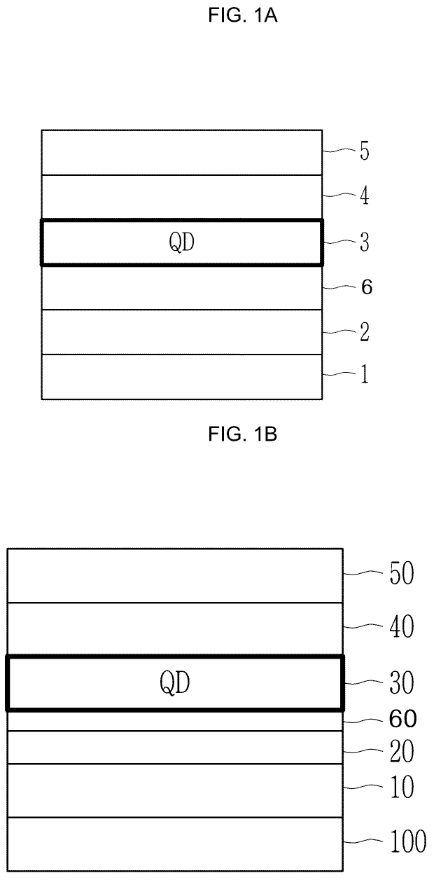

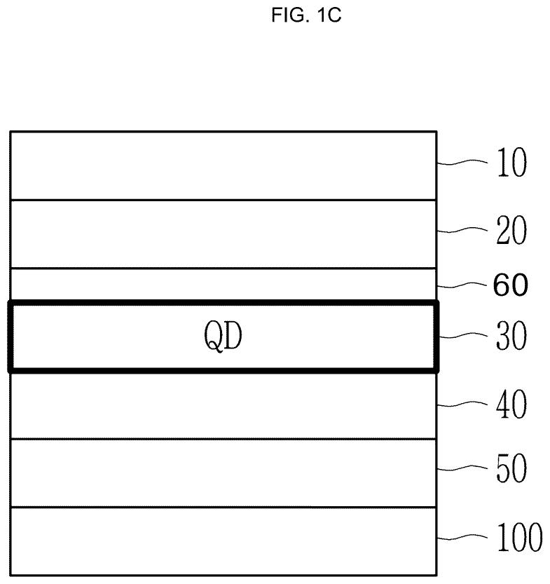

In an embodiment, the electroluminescent device includes a first electrode 1 or 10, see, FIGS. 1A and 1B, respectively, and a second electrode 5 or 50 spaced apart (e.g., each with surface facing the other); a quantum dot layer 3 or 30 disposed between the first electrode and the second electrode and including a semiconductor nanoparticle (or a population thereof); and optionally, an electron auxiliary (transport) layer 4 or 40 included between the quantum dot layer 3 or 30 and the second electrode 5 or 50. The semiconductor nanoparticle or a population thereof may include a quantum dot (or a population of quantum dots). The electron auxiliary (transport) layer may include a zinc oxide nanoparticle.

The electroluminescent device further includes a first layer 6 or 60 including a inorganic nanoparticle (e.g., a plurality of inorganic nanoparticles) disposed between the quantum dot layer 3 or 30 and the first electrode 1 or 10. The inorganic nanoparticle includes a metal chalcogenide including a Group II metal (e.g., a Group IIA metal or a Group IIB metal) and a chalcogen element (sulfur, selenium, tellurium, or a combination thereof). The (plurality of) inorganic nanoparticle(s) have a size (e.g., an average size) of greater than or equal to about 0.5 nm and less than or equal to about 30 nm.

Hereinafter, a structure of the electroluminescent device of an embodiment will be described with reference to the drawings. Referring to FIGS. 1A, 1B, and 1C, the electroluminescent device of an embodiment includes a quantum dot layer (QD) 3, or 30 including a quantum dot (e.g., a plurality of the quantum dots) and a first layer 6 or 60 disposed between the first electrode 1 or 10 and the quantum dot layer 3 or 30 and including the inorganic nanoparticle (e.g., the plurality of the inorganic nanoparticles). In an embodiment, the quantum dot layer 3 or 30 may be configured to emit first light. For example, the quantum dot may be configured to emit first light. An additional electron auxiliary layer (e.g., an electron injection layer or a hole blocking layer) may be further disposed between the second electrode 5 or 50 and the electron transport layer 4 or 40. The electroluminescent device may further include a hole auxiliary layer 2 or 20 between the quantum dot layer 3 or 30 and the first electrodes 1 and 10. The hole auxiliary layer may include a hole transport layer (including, for example, an organic compound), a hole injection layer, or a combination thereof.

In a device of an embodiment, the anode 10 disposed on the transparent substrate 100 may include a metal oxide-based transparent electrode (e.g., an ITO electrode), and a cathode 50 facing the anode and the cathode may include a conductive metal (Mg, Al, etc.). In a device of an embodiment, the cathode 50 disposed on a transparent substrate 100 may include a metal oxide-based transparent electrode (e.g., an ITO electrode), and the anode 10 facing the cathode may include a conductive metal (Mg, Al, etc.). A hole auxiliary layer 2 or 20 (e.g., a hole injection layer such as PEDOT:PSS and/or p-type metal oxide and/or a hole transport layer including TFB and/or PVK) may be formed between the anode 10 and the quantum dot layer 3 or 30. The hole injection layer may be close to the anode or the transparent electrode, and the hole transport layer may be close to the quantum dot layer. Between the quantum dot layer 3 or 30 and the cathode 5 or 50, an electron auxiliary layer 4 or 40 such as an electron injection layer/transport layer may be disposed. See, FIGS. 1B and 10.

The first electrode or the second electrode may include an anode or a cathode. In an embodiment, the first electrode may include a cathode (or anode) and the second electrode may include an anode (or cathode). In an embodiment, the second electrode includes a cathode. In the electroluminescence device, the first electrode (or the second electrode) may be disposed on a (transparent) substrate. The quantum dot layer may be disposed within a pixel (or sub-pixel) in a display device (display panel) to be described later.

The quantum dot layer 3 or 30 may be disposed between the first electrodes (e.g., anodes) 1 and 10 and the second electrodes (e.g., cathodes) 5 and 50. The second electrodes or cathode 5 or 50 may include an electron injection conductor. The first electrodes or anode 1 or 10 may include a hole injection conductor. The work functions of the electron/hole injection conductors included in the second electrode and the first electrode may be appropriately adjusted and are not particularly limited. For example, the second electrode may have a small work function and the first electrode may have a relatively large work function, or vice versa.

The electron/hole injection conductors may include a metal-based material (e.g., a metal, a metal compound, an alloy, or a combination thereof) (aluminum, magnesium, tungsten, nickel, cobalt, platinum, palladium, calcium, LiF, etc.), a metal oxide such as gallium indium oxide or indium tin oxide (ITO), or a conductive polymer (e.g., having a relatively high work function) such as polyethylene dioxythiophene, but are not limited thereto.

At least one of the first electrode and the second electrode may be a light-transmitting electrode or a transparent electrode. In an embodiment, both the first electrode and the second electrode may be a light-transmitting electrode. The electrode(s) may be patterned.

The first electrode and/or the second electrode may be disposed on a (e.g., insulating) substrate. The substrate may be a substrate including an insulating material. The substrate may include glass; various polymers such as polyester, polycarbonate, polyacrylate, etc., such as polyethylene terephthalate (PET) and polyethylene naphthalate (PEN); polysiloxane (e.g. PDMS); inorganic materials such as Al₂O₃ and ZnO; or a combination thereof, but is not limited thereto. A thickness of the substrate may be appropriately selected in consideration of the substrate material, etc., and is not particularly limited. The substrate may be flexible.

The substrate may be optically transparent, e.g., may have a light transmittance of greater than or equal to about 50%, greater than or equal to about 60%, greater than or equal to about 70%, greater than or equal to about 80%, greater than or equal to about 85%, or greater than or equal to about 90% and for example, less than or equal to about 99%, or less than or equal to about 95%. The substrate has a light transmittance of greater than or equal to about 50%, greater than or equal to about 60%, greater than or equal to about 70%, greater than or equal to about 80%, greater than or equal to about 85%, greater than or equal to about 90%, greater than or equal to about 99%, or 100%, and for example, less than or equal to about 99%, less than or equal to about 95%, or less than or equal to about 80% for light emitted from the semiconductor nanoparticle. The substrate may include a region for a blue pixel, a region for a red pixel, a region for a green pixel, or a combination thereof.

In an embodiment, a thin film transistor may be disposed in each region of the substrate but is not limited thereto. In an embodiment, either the source electrode or the drain electrode of the thin film transistor may be electrically connected to the first electrode or the second electrode. In an embodiment, the light-transmitting electrode may be disposed on a transparent (e.g., insulating) substrate. The substrate may be a rigid substrate or a flexible substrate.

The light-transmitting electrode may include, for example, a transparent conductor such as indium tin oxide (ITO) or indium zinc oxide (IZO), gallium indium tin oxide, zinc indium tin oxide, titanium nitride, polyaniline, LiF/Mg:Ag, or the like, or a metal thin film of a single layer or a plurality of layers, but is not limited thereto. In an embodiment, either the first electrode or the second electrode may be an opaque electrode including aluminum (Al), a lithium-aluminum (Li:Al) alloy, a magnesium-silver alloy (Mg;Ag), lithium fluoride-aluminum (LiF:Al), or a combination thereof.

A thickness of the electrode (the first electrode and/or the second electrode) is not particularly limited and may be appropriately selected in consideration of device efficiency. In an embodiment, the thickness of the electrode may be greater than or equal to about 5 nm, for example, greater than or equal to about 10 nm, greater than or equal to about 20 nm, greater than or equal to about 30 nm, greater than or equal to about 40 nm, or greater than or equal to about 50 nm. In an embodiment, the thickness of the electrode may be less than or equal to about 100 μm, for example, less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, or less than or equal to about 100 nm.

A light emitting layer or a quantum dot layer 3 or 30 may be disposed between the first electrodes and the second electrode (e.g., the anode and cathode). The quantum dot layer includes (e.g., blue light emitting, green light emitting, or red light emitting) quantum dot(s).

The quantum dot layer may be patterned. For example, the quantum dot layer may be patterned by a inkjet printing process, but is not limited thereto. In an embodiment, the patterned light emitting layer (or a quantum dot layer) may include a blue light emitting layer (or a blue light emitting quantum dot layer), e.g., disposed within a blue pixel in a display device described later, a red light emitting layer (or a red light emitting quantum dot layer), e.g., disposed within a red pixel in a display device described later, a green light emitting layer (or a green light emitting quantum dot layer), e.g., disposed within a green pixel in a display device to be described later, or a combination thereof. Each light emitting layer (or quantum dot layer) may be separated, e.g., optically from an adjacent light emitting layer (or quantum dot layer) by a partition wall. In an embodiment, a partition wall, e.g. a black matrix, a bank, etc. may be disposed between the red light emitting layer(s), the green light emitting layer(s), and the blue light emitting layer(s). In an embodiment, each light emitting layer (or quantum dot layer) may be substantially optically isolated.

The quantum dot layer or the quantum dot may not contain cadmium. The quantum dot layer or the quantum dot may not contain mercury, lead, or a combination thereof.

In an embodiment, the quantum dot may include a semiconductor nanocrystal. The quantum dot may have a core/shell structure. In an embodiment, the quantum dot or the core/shell structure may include a core including a first semiconductor nanocrystal and a shell including a second semiconductor nanocrystal disposed on the core and having a different composition from the first semiconductor nanocrystal.

The quantum dot, the first semiconductor nanocrystal, or the second semiconductor nanocrystal may include a Group II-VI compound, a Group III-V compound, a Group IV-VI compound, a Group IV element or compound, a Group I-III-VI compound, a Group I-II-IV-VI compound, or a combination thereof. The quantum dot, (or the first semiconductor nanocrystal or the second semiconductor nanocrystal) or the quantum dot layer may not contain a harmful heavy metal such as cadmium, lead, mercury, or a combination thereof.

The Group II-VI compound may include a binary compound selected from ZnS, ZnSe, ZnTe, ZnO, HgS, HgSe, HgTe, MgSe, MgS, and a mixture thereof; a ternary compound selected from ZnSeS, ZnSeTe, ZnSTe, HgSeS, HgSeTe, HgSTe, HgZnS, HgZnSe, HgZnTe, MgZnSe, MgZnS, and a mixture thereof; and a quaternary compound selected from HgZnTeS, HgZnSeS, HgZnSeTe, HgZnSTe, and a mixture thereof. The Group II-VI compound may further include a Group III metal.

The Group III-V compound may include a binary compound selected from GaN, GaP, GaAs, GaSb, AlN, AlP, AIAs, AlSb, InN, InP, InAs, InSb, and a mixture thereof; a ternary compound selected from GaNP, GaNAs, GaNSb, GaPAs, GaPSb, AlNP, AlNAs, AlNSb, AlPAs, AlPSb, InNP, InNAs, InNSb, InPAs, InPSb, and a mixture thereof; and a quaternary compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II element. An example of such a semiconductor nanocrystal include InZnP.

The Group IV-VI compound may be a binary compound selected from SnS, SnSe, SnTe, and a mixture thereof; a ternary compound selected from SnSeS, SnSeTe, SnSTe, and a mixture thereof; and a quaternary compound such as SnSSeTe. Examples of the Group I-III-VI compound include CuInSe₂, CuInS₂, CuInGaSe, and CuInGaS but are not limited thereto.

Examples of the group I-II-IV-VI compound include, but are not limited to, CuZnSnSe and CuZnSnS.

The Group IV element or compound is a single element selected from Si, Ge, and a mixture thereof; and a binary compound selected from SiC, SiGe, and a mixture thereof.

In an embodiment, the semiconductor nanocrystal (first or second semiconductor nanocrystal) may include a metal including indium, zinc, or a combination thereof and a non-metal including phosphorus, selenium, tellurium, sulfur, or a combination thereof.

In an embodiment, the first semiconductor nanocrystal may include InP, InZnP, ZnSe, ZnSeS, ZnSeTe, or a combination thereof and/or the second semiconductor nanocrystal may include ZnSe, ZnSeS, ZnS, ZnTeSe, or a combination thereof. In an embodiment, the shell may include zinc, sulfur, and optionally selenium in an outermost layer of the quantum dot.

In an embodiment, the quantum dot may emit blue or green light and have a core including ZnSeTe, ZnSe, or a combination thereof and a shell including zinc chalcogenide (e.g., ZnS, ZnSe, and/or ZnSeS). An amount of sulfur in the shell may increase or decrease in the radial direction, for example, from the core towards a surface of the quantum dot.

In an embodiment, the quantum dot may emit red or green light, the core or the first semiconductor nanocrystal may include InP, InZnP, or a combination thereof, and the shell or the second semiconductor nanocrystal may include a Group 2 metal including zinc and a non-metal including at least one of sulfur and selenium.

In an embodiment, the quantum dot may have a core/shell structure, an alloyed layer may or may not be present at the interface between the core and the shell. The alloyed layer may be a homogeneous alloy or may be a gradient alloy. In the gradient alloy, a concentration of elements present in the shell may have a concentration gradient that changes in the radial direction (e.g., decreases or increases toward the center).

In an embodiment, the shell or the second semiconductor nanocrystal may have a composition which is changed in a radial direction. In an embodiment, the shell may be a multilayered shell including two or more shell layers. In the multilayered shell, adjacent two layers may have different compositions from each other. In the multilayered shell, at least one layer may each independently include a semiconductor nanocrystal having a single composition. In the multilayered shell, at least one layer may independently have an alloyed semiconductor nanocrystal. In the multilayered shell, at least one layer may have a concentration gradient that radially changes in terms of a composition of a semiconductor nanocrystal.

In the core/shell quantum dot, the bandgap energy of the shell or the second semiconductor nanocrystal may be greater than that of the core or the first semiconductor nanocrystal but is not limited thereto. The bandgap energy of the shell (e.g., the second semiconductor nanocrystal) may be smaller than that of the core (e.g., the first semiconductor nanocrystal). In the case of the multilayered shell, the energy bandgap of the outermost shell layer may be greater than those of the core and an inner shell layer, i.e., a layer that is closer to the core. In the case of the multilayered shell, a semiconductor nanocrystal of each layer is selected to have an appropriate bandgap, thereby effectively showing a quantum confinement effect.

The quantum dot of an embodiment may include, for example, an organic ligand, an organic solvent, or a combination thereof, in a state in which they are bonded or coordinated to the surface of the quantum dot.

In an embodiment, the quantum dot may control the absorption/emission wavelength by, for example, adjusting its composition and/or size. The quantum dots included in the quantum dot layer may be configured to emit light (e.g., a first light) of a desired color.

In an embodiment, a peak emission wavelength of the quantum dot or the first light may have a wavelength range from ultraviolet to infrared wavelengths or longer. For example, a peak emission wavelength may be greater than or equal to about 300 nm, for example, greater than or equal to about 500 nm, greater than or equal to about 510 nm, greater than or equal to about 520 nm, greater than or equal to about 530 nm, greater than or equal to about 540 nm, greater than or equal to about 550 nm, greater than or equal to about 560 nm, greater than or equal to about 570 nm, greater than or equal to about 580 nm, greater than or equal to about 590 nm, greater than or equal to about 600 nm, or greater than or equal to about 610 nm. The peak emission wavelength may be in the range of less than or equal to about 800 nm, for example, less than or equal to about 650 nm, less than or equal to about 640 nm, less than or equal to about 630 nm, less than or equal to about 620 nm, less than or equal to about 610 nm, less than or equal to about 600 nm, less than or equal to about 590 nm, less than or equal to about 580 nm, less than or equal to about 570 nm, less than or equal to about 560 nm, less than or equal to about 550 nm, or less than or equal to about 540 nm. The peak emission wavelength may be in the range of about 500 nm to about 650 nm.

The quantum dot may emit a green light. The peak emission wavelength of the green light may be in the range of greater than or equal to about 500 nm (e.g., greater than or equal to about 510 nm) and less than or equal to about 560 nm (e.g., less than or equal to about 540 nm).

The quantum dot may emit a red light. The peak emission wavelength of the red light may be in the range of greater than or equal to about 600 nm (e.g., greater than or equal to about 610 nm) and less than or equal to about 650 nm (e.g., less than or equal to about 640 nm).

The quantum dot may emit a blue light. The peak emission wavelength of the blue light may be greater than or equal to about 440 nm (e.g., greater than or equal to about 450 nm) and less than or equal to about 480 nm (e.g., less than or equal to about 465 nm).

An emission peak of the quantum dot or the first light may have a relatively narrow full width at half maximum (FWHM). In an embodiment, the full width at half maximum may be less than or equal to about 45 nm, for example less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, or less than or equal to about 35 nm. The full width at half maximum may be greater than or equal to about 1 nm, greater than or equal to about 5 nm, greater than or equal to about 10 nm, greater than or equal to about 12 nm, or greater than or equal to about 15 nm. For example, the FWHM may be less than or equal to about 40 nm and greater than or equal to about 5 nm, or less than or equal to about 40 nm and greater than or equal to about 10 nm.

The quantum dot may have (or may be configured to exhibit) a quantum yield of greater than or equal to about 10%, for example, greater than or equal to about 20%, greater than or equal to about 30%, greater than or equal to about 40%, greater than or equal to about 50%, greater than or equal to about 60%, greater than or equal to about 70%, greater than or equal to about 80%, greater than or equal to about 90%, or even about 100%.

The quantum dot may have a size (e.g., a particle diameter or a particle diameter calculated from a two-dimensional area confirmed by electron microscopy analysis in the case of non-spherical particles) of greater than or equal to about 1 nm and less than or equal to about 100 nm. In an embodiment, the quantum dot may have a size of about 1 nm to about 50 nm, for example, about 2 nm (or about 3 nm) to about 35 nm. In an embodiment, the size of the quantum dot or the semiconductor nanoparticle may be greater than or equal to about 1 nm, greater than or equal to about 2 nm, greater than or equal to about 3 nm, greater than or equal to about 4 nm, or greater than or equal to about 5 nm. In an embodiment, the size of the quantum dot may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, or less than or equal to about 15 nm.

The quantum dot may have any shape. In an embodiment, the shape of the quantum dot may be a sphere, a polyhedron, a pyramid, a multi-pod, a cube, a nanotube, a nanowire, a nanofiber, a nanosheet, a nanoplate, or a combination thereof. The quantum dot may be synthesized by any method. For example, the semiconductor nanocrystal having a size of several nanometers may be synthesized through a wet chemical process. In the wet chemical process, crystal particles are grown by reacting precursor materials in an organic solvent, and growth of crystals may be controlled by coordinating the organic solvent or ligand compound on the surface of the semiconductor nanocrystals.

In an embodiment, for example, the method of preparing the quantum dots having the core/shell structure may include obtaining the core; preparing a first shell precursor solution including a first shell precursor including a metal (e.g., zinc) and an organic ligand; preparing a second shell precursor including a non-metal element (e.g., sulfur, selenium, or a combination thereof); and heating the first shell precursor solution at a reaction temperature (e.g., greater than or equal to about 180° C., greater than or equal to about 200° C., greater than or equal to about 240° C., or greater than or equal to about 280° C. and less than or equal to about 360° C., less than or equal to about 340° C., or less than or equal to about 320° C.) and then, adding the core and the second shell precursor thereto to form a shell of second semiconductor nanocrystals on the first semiconductor nanocrystal core.

In the semiconductor nanoparticles of an embodiment, the core may be prepared by an appropriate method. The method may further include preparing a core solution by separating the core from a reaction system used for preparing the core and then, dispersing it in an organic solvent.

In an example embodiment, to form the shell, a solvent and optionally, a ligand compound are heated at a predetermined temperature (e.g., greater than or equal to about 100° C.) under vacuum (or vacuum-treated). Nitrogen may be then added to the reactor and the reaction mixture heat-treated again at a predetermined temperature (e.g., greater than or equal to 100° C.). The core may be then added to the heated reactor, and the shell precursors are sequentially or simultaneously added, and the reaction mixture may be heated at a predetermined reaction temperature to perform a reaction. The shell precursors may be sequentially introduced in different proportions of the mixture as the reaction proceeds, for example, to provide one or more shell layers with a gradient concentration in a direction from the core.

The organic solvent may include a C6 to C22 primary amine such as a hexadecylamine, a C6 to C22 secondary amine such as dioctylamine, a C6 to C40 tertiary amine such as a trioctyl amine, a nitrogen-containing heterocyclic compound such as pyridine, a C6 to C40 olefin such as octadecene, a C6 to C40 aliphatic hydrocarbon such as hexadecane, octadecane, or squalane, an aromatic hydrocarbon substituted with a C6 to C30 alkyl group such as phenyldodecane, phenyltetradecane, or phenyl hexadecane, a primary, secondary, or tertiary phosphine (e.g., trioctylamine) substituted with at least one (e.g., 1, 2, or 3) C6 to C22 alkyl group, a phosphine oxide (e.g. trioctylphosphine oxide) substituted with a (e.g., 1, 2, or 3) C6 to C22 alkyl group, a C12 to C22 aromatic ether such as phenyl ether or benzyl ether, or a combination thereof.

The organic ligand or the organic solvent may coordinate to the surface of the prepared semiconductor nanoparticles. The organic ligand may ensure that the semiconductor nanoparticles or quantum dots are well dispersed in a solution. The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH, or a combination thereof, wherein, each R and R′ independently include C1 or more, C6 or more, or 010 or more and C40 or less, C35 or less, or C25 or less substituted or unsubstituted aliphatic hydrocarbon, or C6 to C40 substituted or unsubstituted aromatic hydrocarbon, or a combination thereof. The ligand may be used alone or as a mixture of two or more compounds.

Metal precursors may include a metal powder, an alkylated metal, a metal alkoxide, a metal carboxylate, a metal halide, a metal cyanide, a metal hydroxide, a metal oxide, a metal nitrate, a metal perchlorate, a metal acetylacetonate, a metal peroxide, or a combination thereof, but are not limited thereto. In an embodiment, the metal precursor may be a Zn metal powder, an alkylated Zn compound, a Zn alkoxide, a C2 to 010 Zn carboxylate, a Zn nitrate, a Zn perchlorate, a Zn sulfate, a Zn acetylacetonate, a Zn halide, a Zn cyanide, a Zn hydroxide, a Zn oxide, a Zn peroxide, or a combination thereof.

The chalcogen precursor may include a selenium precursor, a sulfur precursor, or a tellurium precursor. The selenium precursor may include selenium-trioctylphosphine (Se-TOP), selenium-tributylphosphine (Se-TBP), selenium-triphenylphosphine (Se-TPP), selenium-diphenylphosphine (Se-DPP), or a combination thereof, but is not limited thereto.

The sulfur precursor may include mercapto propyl silane, sulfur-trioctylphosphine (S-TOP), sulfur-tributylphosphine (S-TBP), sulfur-triphenylphosphine (S-TPP), sulfur-trioctyl amine (S-TOA), bis(trimethylsilylmethyl) sulfide, bis(trimethylsilyl)sulfide, ammonium sulfide, sodium sulfide, or a combination thereof.

The semiconductor nanocrystals may be recovered by pouring into an excess of nonsolvent to remove excess organic matter not coordinated on the surface and centrifuging the resulting mixture. The nonsolvent may be a polar solvent that is miscible with the solvent used in the core formation and/or shell formation reactions and is not capable of dispersing the prepared nanocrystals. The nonsolvent may be selected depending on the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, a solvent having a similar solubility parameter to the foregoing non-solvents, or a combination thereof. The recovery or the separation of the semiconductor nanocrystal particle or the quantum dot may include centrifugation, sedimentation, chromatography, or distillation. The separated nanocrystal or quantum dot may be added to a washing solvent and washed, if needed. The washing solvent has no particular limit and may have a similar solubility parameter to that of the ligand and may, for example, include hexane, heptane, octane, chloroform, toluene, benzene, and the like.

The quantum dot may be non-dispersible or insoluble in water, the aforementioned nonsolvent, or a combination thereof. The quantum dot may be dispersed in the aforementioned organic solvent. In an embodiment, the quantum dot may be dispersed in C6 to C40 aliphatic hydrocarbon, C6 to C40 substituted or unsubstituted aromatic hydrocarbon, or a combination thereof.

The surface of the prepared quantum dot may be treated with a halogen compound. By halogen treatment, some organic ligands present in the semiconductor nanoparticles may be replaced with a halogen. The halogen-treated semiconductor nanoparticles may contain a reduced content of organic ligand. The halogen treatment may be performed by contacting semiconductor nanoparticles with a halogen compound (e.g., a metal halide such as zinc chloride) at a predetermined temperature, for example, about 30° C. to about 100° C., or about 50° C. to about 150° C. in an organic solvent. The halogen-treated semiconductor nanoparticles may be separated using the aforementioned nonsolvent.

In an embodiment, the quantum dot layer 3 or 30 may include a monolayer(s) of quantum dots. The quantum dot layer 3 or 30 may include one or more, for example, two or more, three or more, or four or more and 20 or less, 10 or less, 9 or less, 8 or less, 7 or less, or 6 or less monolayers of quantum dots. In an embodiment, the quantum dot layer 3 or 30 may have a thickness of greater than or equal to about 5 nm, for example, greater than or equal to about 10 nm, greater than or equal to about 15 nm, greater than or equal to about 20 nm, greater than or equal to about 25 nm, or greater than or equal to about 30 nm and less than or equal to about 200 nm, for example, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The quantum dot layer 3 or 30 may have a thickness of, for example about 10 nm to about 150 nm, for example about 20 nm to about 100 nm, for example about 30 nm to about 50 nm. In an embodiment, the quantum dot layer 3 or 30 may have a thickness of greater than or equal to about 5 nm, or greater than or equal to about 7 nm. The quantum dot layer may have a thickness of less than or equal to about 80 nm, or less than or equal to about 50 nm.

In an embodiment, the quantum dot layer may not include an inorganic nanoparticle as described herein. In another embodiment, the quantum dot layer may further include an inorganic nanoparticle as described herein.

In an embodiment, the formation of a quantum dot layer (or QD light emitting layer) using the quantum dots is the same as described herein.

In an embodiment of an electroluminescent device (e.g., QD-LED), a hole auxiliary layer such as a hole transport layer (HTL) may be disposed between the first electrode and the light emitting layer so that holes can readily migrate to the QD light emitting layer. In an embodiment, a difference between the HOMO/LUMO level of the hole auxiliary layer and the HOMO/LUMO level of the light emitting layer may be controlled to facilitate a supply of the holes. The present inventors have found that the hole auxiliary layer (e.g., HTL) adjacent to the light emitting layer and having a LUMO sufficiently lower than the LUMO of the light emitting layer (in other words, a relatively large difference between the LUMO level of the light emitting layer and the LUMO level of hole auxiliary layer) may more effectively block the electrons from entering the HTL. The present inventors have found that a shallow LUMO level of the hole auxiliary layer (e.g., HTL) may improve an external quantum efficiency of the device.

However, the present inventors have also found that a hole auxiliary layer (e.g., HTL) having adjusted LUMO and HOMO levels with respect to the light emitting layer may result in deterioration of the life-span of the device. The present inventors have found that in case where a hole auxiliary layer having a shallow LUMO level is disposed adjacent to the light emitting layer, the life-span of the device may be significantly reduced. Without wishing to be bound by any theory, a hole auxiliary layer (e.g., HTL, etc.) with an adjusted (e.g. a shallow) energy level may be prone to have HTL traps, which may readily bring about an electron charging within the hole auxiliary layer, leading to a deterioration of the HTL and causing the collapse of the electron-hole balance of the device, and this can have an adverse effect on the life-span of the device.

The present inventors have found that a shell coating of the quantum dot included in the light emitting layer may not have a desirably increased thickness. In addition, a core/shell quantum dot (for example, a blue light emitting quantum dot) having a zinc chalcogenide core and a zinc chalcogenide (e.g., ZnS) shell may not have a sufficient confinement at the LUMO level through which electrons may flow. Without wishing to be bound by any theory, it is believed that such an insufficient electron confinement in the light emitting layer of an electroluminescent device may cause an electron to easily pass through the QD layer and to readily enter the hole auxiliary layer (e.g., HTL) after the turn-on voltage. The electrons that enter into the HTL may cause HTL deterioration.

The electroluminescent device of an embodiment further includes a first layer including a (plurality of) inorganic nanoparticle(s) between the quantum dot layer and the first electrode (e.g., anode), and the inorganic nanoparticle includes a metal chalcogenide including a Group II metal and a chalcogen element, and the plurality of inorganic nanoparticles have a size of greater than or equal to about 0.5 nm and less than or equal to about 30 nm. The electroluminescent device of an embodiment may further include a hole auxiliary layer between the first electrode and the first layer or between the first electrode and the quantum dot layer. The hole auxiliary layer may further include a hole transport layer, for example, including a hole transporting organic compound, a hole injection layer, or a combination thereof. The hole transport layer may be disposed proximate or closer to the first layer. The hole injection layer may be disposed proximate or closer to the first electrode. In an embodiment, the hole transport layer may be disposed between the first layer and the hole injection layer.

In the hole transport layer, the hole transporting organic compound may include a compound (e.g., a non-polymeric compound such as a molecular compound or a (co)polymeric compound) including a substituted or unsubstituted fluorenyl moiety, a substituted or unsubstituted diphenylamine moiety, a (twisted) triphenylamine moiety, or a combination thereof (for example, in a backbone thereof); or a combination thereof (e.g., a mixture of two or more compounds). The hole injection layer may include a hole injection organic compound, a hole transporting inorganic material, or a combination thereof. In an embodiment, the hole transporting organic compound may include a fluorene compound substituted with a substituted or unsubstituted aryl amine group (e.g., a triphenyl amine group), a substituted or unsubstituted C1 to C30 or C4-C28 alkyl group, a carbazole group, or a combination thereof.

In the electroluminescent device of an embodiment, when present, the hole auxiliary layer (e.g., the hole transport layer and/or the hole injection layer) may each independently include poly(9,9-dioctyl-fluorene-co-N-(4)-butylphenyl)-diphenylamine) (TFB), polyarylamine, poly(N-vinylcarbazole), poly(3,4-ethylenedioxythiophene) (PEDOT), poly(3,4-ethylenedioxythiophene) polystyrene sulfonate (PEDOT:PSS), polyaniline, polypyrrole, N,N,N′,N′-tetrakis(4-methoxyphenyl)-benzidine (TPD), 4,4′-bis[N-(1-naphthyl)-N-phenyl-amino]biphenyl (alpha-NPD), m-MTDATA (4,4′,4″-Tris[phenyl(m-tolyl)amino]triphenylamine), 4,4′,4″-tris(N-carbazolyl)-triphenylamine (TCTA), 1,1-bis[(di-4-toylamino)phenylcyclohexane (TAPC), a p-type metal oxide (e.g., NiO, WO₃, MoO₃, etc.), a carbon-based material such as graphene oxide, a perovskite thin film (including, for example, a perovskite crystal based on an alkali metal transition metal halide, such as cesium lead chloride, or an alkaline earth metal transition metal chalcogenide), or a combination thereof. The hole transporting organic compound or the hole injecting organic compound of an embodiment may be appropriately selected to satisfy the arrangement of HOMO/LUMO levels as described herein. In an embodiment, the hole transport layer may have a HOMO level of about 5 eV to about 5.78 eV, about 5.2 eV to about 5.65 eV, or about 5.3 eV to about 5.58 eV, or about 5.4 eV to about 5.52 eV, or about 5.5 eV, but is not limited thereto.

A thickness of the hole transport layer or the hole injection layer may be appropriately selected and are not particularly limited. The thickness of the hole transport layer, the hole injection layer, or a combination of the hole transport and the hole injection layers may be may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, for example, less than or equal to about 40 nm, less than or equal to about 35 nm, or less than or equal to about 30 nm.

The first layer as described herein may be disposed between the first electrode and the quantum dot layer and, if present, between a hole auxiliary layer (e.g., a hole transport layer) and the quantum dot layer. The first layer may have a relatively wide bandgap energy and may have a HOMO level that is appropriately matches with the quantum dot layer. The first layer may effectively prevent electrons from reaching the hole auxiliary layer (e.g., hole transport layer) from the light emitting layer. The electroluminescent device of an embodiment may effectively suppress deterioration of the hole auxiliary layer due to electrons that may enter the hole auxiliary layer, and therefore, exhibit increased life-span while achieving high luminous efficiency (e.g., EQE).

The inorganic nanoparticle may have a composition that is different than the plurality of quantum dots. The Group II metal may include a metal including zinc, magnesium, calcium, barium, strontium, or a combination thereof. The chalcogen element may include selenium, sulfur, tellurium, or a combination thereof. The chalcogen element may not include oxygen. In an embodiment, the inorganic nanoparticle may include or may not include a metal oxide (e.g., a zinc oxide).

The metal chalcogenide may include magnesium sulfide, magnesium selenide, magnesium sulfide selenide, zinc magnesium selenide, zinc magnesium sulfide, zinc sulfide, zinc selenide sulfide, barium sulfide, barium selenide, barium sulfide selenide, calcium sulfide, calcium selenide, calcium selenide sulfide, or a combination thereof. In an embodiment, the inorganic nanoparticle may include zinc sulfide. The metal chalcogenide may include two or more types of compounds.

The HOMO energy level (e.g., a HOMO energy level in a bulk state, hereinafter referred to as a HOMO energy level) of the metal chalcogenide (or the first layer, hereinafter referred to as a metal chalcogenide) may be smaller (or shallower) than the HOMO energy level of the quantum dot layer. The HOMO energy level of the metal chalcogenide may be larger (or deeper) than the HOMO energy level of the quantum dot layer. The HOMO energy level of the metal chalcogenide may be substantially the same as the HOMO energy level of the quantum dot layer.

A difference between the HOMO energy level of the metal chalcogenide and the HOMO energy level of the quantum dot layer may be less than or equal to about 0.5 eV, less than or equal to about 0.3 eV, less than or equal to about 0.28 eV, less than or equal to about 0.25 eV, less than or equal to about 0.2 eV, less than or equal to about 0.18 eV, less than or equal to about 0.15 eV, less than or equal to about 0.12 eV, less than or equal to about 0.1 eV, less than or equal to about 0.08 eV, less than or equal to about 0.06 eV, or less than or equal to about 0.05 eV. The difference between the HOMO energy level of the metal chalcogenide and the HOMO energy level of the quantum dot layer may be greater than or equal to about 0.001 eV, greater than or equal to about 0.005 eV, greater than or equal to about 0.01 eV, greater than or equal to about 0.02 eV, greater than or equal to about 0.03 eV, greater than or equal to about 0.04 eV, greater than or equal to about 0.07 eV, or greater than or equal to about 0.09 eV.

The metal chalcogenide included in the plurality of inorganic nanoparticles may have a bandgap energy (e.g., in a bulk state) of greater than or equal to about 3.0 eV, greater than or equal to about 3.2 eV, greater than or equal to about 3.4 eV, greater than or equal to about 3.5 eV, greater than or equal to about 3.7 eV, greater than or equal to about 3.8 eV, greater than or equal to about 3.9 eV, greater than or equal to about 4 eV, greater than or equal to about 4.2 eV, greater than or equal to about 4.4 eV, greater than or equal to about 4.6 eV, greater than or equal to about 4.8 eV, or greater than or equal to about 5 eV. The bandgap energy of the metal chalcogenide may less than or equal to about 6 eV, less than or equal to about 5.8 eV, less than or equal to about 5.5 eV, less than or equal to about 5 eV, less than or equal to about 4.5 eV, less than or equal to about 4 eV, less than or equal to about 3.85 eV, less than or equal to about 3.75 eV, or less than or equal to about 3.5 eV.

The LUMO energy level (e.g., a LUMO energy level in a bulk state, hereinafter referred to as LUMO energy level) of the metal chalcogenide may be smaller (or shallower) than the LUMO energy level of the quantum dot layer. A difference between the LUMO energy of the metal chalcogenide and the LUMO energy of the quantum dot layer may be greater than or equal to about 0.3 eV, greater than or equal to about 0.5 eV, greater than or equal to about 0.7 eV, greater than or equal to about 0.8 eV, greater than or equal to about 0.9 eV, greater than or equal to about 1 eV, greater than or equal to about 1.02 eV, greater than or equal to about 1.1 eV, greater than or equal to about 1.2 eV, greater than or equal to about 1.5 eV, or greater than or equal to about 1.8 eV. The difference between the LUMO energy of the metal chalcogenide and the LUMO energy of the quantum dot layer may be less than or equal to about 3.5 eV, less than or equal to about 3 eV, less than or equal to about 2.5 eV, less than or equal to about 2 eV, less than or equal to about 1.8 eV, less than or equal to about 1.3 eV, less than or equal to about 1.0 eV, or less than or equal to about 0.7 eV.

In an embodiment, the hole transport layer may be present, and the LUMO energy level of the hole transport layer may be larger (or deeper) than the LUMO energy level of the metal chalcogenide. The LUMO energy level of the hole transport layer may be less than or equal to (shallower or equal to) the LUMO energy level of the metal chalcogenide. A difference between the LUMO energy level of the hole transport layer and the LUMO energy level of the metal chalcogenide may be greater than or equal to about 0.05 eV, greater than or equal to about 0.1 eV, greater than or equal to about 0.15 eV, greater than or equal to about 0.2 eV, greater than or equal to about 0.25 eV, greater than or equal to about 0.3 eV, greater than or equal to about 0.35 eV, greater than or equal to about 0.4 eV, greater than or equal to about 0.45 eV, greater than or equal to about 0.5 eV, greater than or equal to about 0.55 eV, greater than or equal to about 0.6 eV, greater than or equal to about 0.65 eV, greater than or equal to about 0.7 eV, or greater than or equal to about 0.8 eV. The difference between the LUMO energy level of the hole transport layer and the LUMO energy level of the metal chalcogenide may be less than or equal to about 2 eV, less than or equal to about 1.5 eV, less than or equal to about 1.3 eV, less than or equal to about 1.1 eV, less than or equal to about 0.9 eV, or less than or equal to about 0.7 eV.

In an embodiment, the hole transport layer may be present, and the HOMO energy level of the hole transport layer may be larger (deeper) than the HOMO energy level of the metal chalcogenide. The HOMO energy level of the hole transport layer may be smaller than or equal to (shallower or equal to) the HOMO energy level of the metal chalcogenide. A difference between the HOMO energy level of the metal chalcogenide and the HOMO energy level of the hole transport layer may be less than or equal to about 1 eV, less than or equal to about 0.7 eV, less than or equal to about 0.5 eV, less than or equal to about 0.3 eV, less than or equal to about 0.28 eV, less than or equal to about 0.25 eV, less than or equal to about 0.2 eV, less than or equal to about 0.18 eV, less than or equal to about 0.15 eV, less than or equal to about 0.12 eV, less than or equal to about 0.1 eV, less than or equal to about 0.08 eV, less than or equal to about 0.06 eV, or less than or equal to about 0.05 eV. The difference between the HOMO energy level of the metal chalcogenide and the HOMO energy level of the hole transport layer may be greater than or equal to about 0.01 eV, greater than or equal to about 0.02 eV, greater than or equal to about 0.03 eV, greater than or equal to about 0.04 eV, greater than or equal to about 0.07 eV, greater than or equal to about 0.09 eV, greater than or equal to about 0.1 eV, greater than or equal to about 0.12 eV, or greater than or equal to about 0.15 eV.

The energy level between the hole injection layer and the hole transport layer may be appropriately selected. In an embodiment, the HOMO energy level of the hole injection layer may be smaller than the HOMO energy level of the hole transport layer, and the difference between them may be less than or equal to about 1.5 eV, less than or equal to about 1 eV, or less than or equal to about 0.9 eV and greater than or equal to about 0.1 eV or greater than or equal to about 0.4 eV.

An electroluminescent device according to non-limiting embodiment may exhibit LUMO/HOMO energy levels as shown below (see Table 1).

TABLE 1

| | | LUMO level | HOMO level |
|---|---|---|---|
| | | (eV) | (eV) |
| Electron transport layer | | −3.8 | |
| (including zinc oxide) | | | |
| QD layer | | −3.05 | −5.75 |
| First layer | | −2.0 | −5.7 or −5.78 |
| HTL | HTL 1 | −2.7 or −2.68 | −5.5 or −5.52 |
| | HTL 2 | −2.2 or −2.23 | −5.6 or −5.58 |

| | |
|---|---|
| HIL | −5.1 |

Either HTL 1 or HTL 2 can be used, or both HTL 1 and HTL 2 can be present in the device. By the band alignment as described herein, a high EQE property from the electronic blocking can be secured, and the HTL electron resistance may be strengthened, a life-span of the device may be increased, and degradation of hole conduction characteristics may be suppressed.

The inorganic nanoparticle(s) have an (average) size of greater than or equal to about 1 nm, greater than or equal to about 2 nm, greater than or equal to about 2.5 nm, greater than or equal to about 3 nm, greater than or equal to about 3.5 nm, greater than or equal to about 4 nm, greater than or equal to about 4.5 nm, greater than or equal to about 5 nm, greater than or equal to about 5.5 nm, or greater than or equal to about 6 nm.

The inorganic nanoparticle(s) have an (average) size of less than or equal to about 30 nm, less than or equal to about 25 nm, less than or equal to about 20 nm, less than or equal to about 18 nm, less than or equal to about 17 nm, less than or equal to about 15 nm, less than or equal to about 13 nm, less than or equal to about 11 nm, less than or equal to about 10 nm, less than or equal to about 9 nm, less than or equal to about 8 nm, less than or equal to about 7.5 nm, less than or equal to about 7 nm, less than or equal to about 6.5 nm, less than or equal to about 6 nm, or less than or equal to about 5.4 nm.

The inorganic nanoparticle may be synthesized by an appropriate method or are commercially available. The inorganic nanoparticle may be prepared by a chemical wet method using appropriate precursors and may include ligands (e.g., substituted or present during synthesis) on the surface. For example, the inorganic nanoparticle may be synthesized by a chemical wet method by reaction between a precursor including the aforementioned metal (e.g., metal powder, metal carboxylate, metal acetate, etc.) and a chalcogen precursor (e.g., a selenium precursor, a tellurium precursor, a sulfur precursor, or a combination thereof) in an organic solvent and in the presence of a first organic ligand. The reaction temperature and reaction time may be appropriately selected and each is not particularly limited. Additional details as to the first organic ligand, the organic solvent, and the precursor may be referred to as described in the synthesis of quantum dot but not limited thereto.

The plurality of inorganic nanoparticles may further include a second organic ligand bound to the surface. In an embodiment, the inorganic nanoparticle may undergo a surface substitution reaction (i.e., a ligand exchange reaction) using a second organic ligand, and the introduction of the first layer including ligand exchanged inorganic nanoparticle (e.g. a zinc sulfide nanoparticle) may contribute to achieving increased EQE and increased life-span of the electroluminescent device. Although not intended to be bound by a specific theory, surface ligand exchange of inorganic nanoparticles may affect the LUMO level, HOMO level, or a both, and thereby, the HOMO level between the quantum dot layer and the first layer may be better matched.

The second organic ligand may include a bifunctional or polyfunctional organic compound. The second organic ligand may include a compound represented by Chemical Formula 1:

A-L-B Chemical Formula 1

L is a single bond, a substituted or unsubstituted C1 to C30 or C50 aliphatic hydrocarbon group, a substituted or unsubstituted C4 or C6 to C50 or C30 aromatic hydrocarbon group, or a combination thereof, and

A and B are each independently a thiol group (—SH), a carboxylic group (—COOH), a hydroxy group (—OH), an amino group (—NHR wherein R is hydrogen or an C1 to C30 alkyl group), a phosphonic acid group (—PO₃R₂, wherein R is independently hydrogen or C1 to C50 or C30 alkyl group, provided that at least one R is hydrogen), a phosphoric acid group (—OP(O)(OR)₂ wherein R is independently hydrogen or a C1 to C50 or C30 alkyl group, provided that at least one R is hydrogen), a phosphinic acid group (—PO₂R₂, wherein R independently includes hydrogen or a C1 to C50 or C30 alkyl group, provided that at least one R is hydrogen), or a moiety (e.g., anionic moiety) derived therefrom (for example, a deprotonated form or a conjugate base form of each of the listed groups).

Either A or B may have a group (for example, a thiolate moiety, a carboxylate moiety, an alkoxylate moiety, or the like) that can interact with a surface of the inorganic nanoparticle.

In an embodiment, at least one methylene in the C1 to C50 or C30 aliphatic hydrocarbon group in L may be replaced by —CO—, —O—, —NH—, —SO—, —SO₂—, —COO—, or a combination of the groups thereof, as desired.

The second organic ligand may include a diacid compound, a mercapto carboxylic acid compound, a mercapto amine compound, a mercapto phosphonic acid compound, a mercaptophosphoric acid compound, a mercaptophosphinic acid compound, a hydroxy carboxylic acid compound, a hydroxy amine compound, a hydroxy phosphinic acid compound, a hydroxyphosphoric acid compound, a hydroxyphosphinic acid compound, or a combination thereof. The foregoing compounds for the organic ligand may include a group (for example, a thiolate, a carboxylate, an alkoxylate, or the like) that can interact with a surface of the inorganic nanoparticle.

The second organic ligand compound may include mercaptopropionic acid, thioglycolic acid, mercaptobutanoic acid, mercaptopentanoic acid, mercaptohexanoic acid, mercaptooctanoic acid, mercaptononanoic acid, mercaptodecanoic acid, mercaptododecanoic acid, mercaptomethanol, mercaptoethanol, mercaptopropanol, mercaptobutanol, mercaptopentanol, mercaptohexanol, mercaptoheptanol, mercaptooctanol, mercaptononanol, mercaptodecanol, mercaptododecanol, a compound derived from any of the foregoing compound having a thiolate moiety, a carboxylate moiety, or an alkoxylate moiety, or a combination thereof.

A process for conducting a ligand exchange reaction at a surface of the inorganic nanoparticle may include mixing prepared inorganic nanoparticles and the second organic ligand compound in an organic solvent (e.g., a substituted or unsubstituted C5 to C20 aliphatic hydrocarbon solvent such as hexane, heptane, octane, etc., a substituted or unsubstituted aromatic hydrocarbon solvent, or a combination thereof) and stirring them. The surface exchange reaction may be performed at a temperature of about room temperature to about 100° C., e.g., about 35° C. to about 85° C., about 38° C. to about 80° C., about 40° C. to about 70° C., about 45° C. to about 55° C., or a combination thereof.

The stirring time is not particularly limited and may be selected appropriately, for example, based in-part on the exchange reaction temperature and the second organic ligand used.

The inorganic nanoparticle may be placed in a water-miscible solvent (e.g., alcohol), for example, by a wet method (e.g., a solution process for ink, etc.). The inorganic nanoparticle may be configured to be dispersed in water or a water-miscible organic solvent. In an embodiment, the plurality of inorganic nanoparticles are dispersed in a water-miscible organic solvent, and a particle diameter measured by a Dynamic light scattering (DLS) analysis may be greater than or equal to about 1 nm, greater than or equal to about 5 nm, greater than or equal to about 7 nm, greater than or equal to about 9 nm, greater than or equal to about 11 nm, or greater than or equal to about 15 nm. In an embodiment, the particle diameter measured by DLS may be less than or equal to about 1000 nm, or less than or equal to about 700 nm, less than or equal to about 300 nm, less than or equal to about 100 nm, less than or equal to about 80 nm, less than or equal to about 60 nm, less than or equal to about 40 nm, less than or equal to about 30 nm, less than or equal to about 14 nm, or less than or equal to about 10 nm.

In an embodiment, formation of the first layer may involve a solution process. The solution process involves dispersing the particles in an organic solvent (e.g., water-miscible organic solvent) and applying the resulting mixture for example to a substrate or a charge auxiliary layer to form a layer. A concentration of the solution for applying may be appropriately selected in consideration of the desired layer thickness, etc., and is not particularly limited. The inorganic nanoparticle may be dispersed in a water-miscible organic solvent (e.g., alcohol), and orthogonality may be ensured during subsequent quantum dot layer formation. For example, in a solution process of preparing a device having a stacked structure, an orthogonal solvent is a solvent that dissolves a given material layer sought to remove and does not dissolve the other material layer for example beneath the given material layer), and the orthogonality may be desired when forming multilayer structure from solutions.

In an embodiment, the formation of the first layer involves obtaining a liquid composition (ink or coating liquid, hereinafter dispersion) including inorganic nanoparticles and an organic solvent and applying or depositing it to the substrate or a charge auxiliary layer (e.g., a hole auxiliary layer) by an appropriate method (e.g., by spin coating, inkjet printing, etc.). After the applying or depositing, the first layer process may then include washing, heat treatment, or a combination thereof, if desired. In an embodiment, the washing and heat treatment conditions for forming a quantum dot layer may be adopted. A thickness of the first layer may be controlled for example by adjusting a concentration of the liquid composition including the inorganic nanoparticle and/or a rotational speed. The concentration of the composition may be greater than or equal to about 2 mg/ml, or greater than or equal to about 3 mg/ml and less than or equal to about 50 mg/ml, or less than or equal to about 40 mg/ml, or less than or equal to about 30 mg/ml, or less than or equal to about 20 mg/ml, or less than or equal to about 10 mg/ml, but is not limited thereto.

The first layer formed may have a thickness of greater than or equal to about 2 nm, greater than or equal to about 3 nm, greater than or equal to about 4 nm, greater than or equal to about 5 nm, greater than or equal to about 7 nm, greater than or equal to about 9 nm, greater than or equal to about 10 nm, greater than or equal to about 11 nm, greater than or equal to about 13 nm, or greater than or equal to about 15 nm. The thickness of the first layer may be less than or equal to about 70 nm, less than or equal to about 60 nm, less than or equal to about 50 nm, less than or equal to about 40 nm, less than or equal to about 35 nm, less than or equal to about 30 nm, less than or equal to about 25 nm, less than or equal to about 20 nm, less than or equal to about 18 nm, less than or equal to about 14 nm, less than or equal to about 12 nm, less than or equal to about 10 nm, less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, or less than or equal to about 2 nm.

The first layer further includes an organic moiety, and a mole ratio of carbon to Group II metal in the first layer may be greater than or equal to about 0.001:1, greater than or equal to about 0.01:1, greater than or equal to about 0.05:1, greater than or equal to about 0.08:1, greater than or equal to about 0.1:1, greater than or equal to about 0.12:1, greater than or equal to about 0.15:1, greater than or equal to about 0.17:1, or greater than or equal to about 0.2:1. The mole ratio of carbon to Group II metal in the first layer may be less than or equal to about 1:1, less than or equal to about 0.7:1, less than or equal to about 0.5:1, less than or equal to about 0.3:1, less than or equal to about 0.25:1, or less than or equal to about 0.19:1.

In an embodiment, the quantum dot layer 3 or 30 may be formed on the first layer. The quantum dot layer may involve a solution process. The solution process includes dispersing the particles in a solvent and applying them to form a layer.

In an embodiment, the formation of the quantum dot layer 3 or 30 may be performed using a liquid composition (ink or coating liquid, hereinafter dispersion) including quantum dots and an organic solvent (e.g., an alkane solvent such as octane or heptane, an aromatic solvent such as toluene, or a combination thereof), and applying or depositing it on a substrate or a charge auxiliary layer (e.g., hole auxiliary layer) by an appropriate method (e.g., by spin coating, inkjet printing, etc.). After the applying or depositing, washing, heat treatment, or a combination thereof may be performed, if desired. The type of organic solvent for the quantum dot dispersion is not particularly limited and may be appropriately selected taking into account the material components to be dispersed and applied/deposited. In an embodiment, the organic solvent may include a (substituted or unsubstituted) aliphatic hydrocarbon organic solvent (e.g., C3 to C30 alkane solvent such as octane), (substituted or unsubstituted) aromatic hydrocarbon organic solvent (e.g., a benzene solvent having a cycloaliphatic moiety, etc.), an acetate solvent, an alcohol solvent, or a combination thereof.

In an embodiment, the formation of the quantum dot layer may further include contacting the film of semiconductor nanoparticles with, for example, a metal halide (e.g., zinc chloride) organic solution (e.g., an alcohol solution). In an embodiment, the quantum dot layer may include a first semiconductor nanoparticle quantum dot layer substituted with halogen (e.g., chlorine) on the surface and a second semiconductor nanoparticle quantum dot layer disposed thereon and having an increased organic ligand content. A halogen (or chlorine) content and the organic material content of the quantum dot layer may be controlled by appropriate means (a post treatment for the formed layer). For example, a thin film of semiconductor nanoparticles having the aforementioned organic ligand (e.g., a carboxylic acid group-containing ligand) is treated with an alcohol solution of metal halide (e.g., zinc halide or zinc chloride) to adjust (decrease) the organic ligand content of the semiconductor nanoparticles in the thin film. This treated layer may have an increased halogen content and exhibit altered dissolution properties for an organic solvent. Accordingly, on the treated quantum dot layer (e.g., first quantum dot layer), a layer (second quantum dot layer) of semiconductor nanoparticles having a different content of an organic ligand (e.g., halogen-treated semiconductor nanoparticles or semiconductor nanoparticles having a carboxylic acid-containing ligand) is subsequently formed.

In the device of an embodiment, the quantum dot layer may have a single layer or a multilayer structure in which two or more layers are stacked. Adjacent layers in the multilayer structure (e.g., a first quantum dot layer and a second quantum dot layer) may be configured to emit the same color. In a multilayer structure, adjacent layers (e.g., a first quantum dot layer and a second quantum dot layer) may have the same or different compositions and/or ligands from each other. In an embodiment, the quantum dot layer or the multilayer quantum dot layer including two or more layers may have a halogen content that changes in a thickness direction. In the (multilayer) quantum dot layer according to an embodiment, the halogen content may increase towards the electron auxiliary layer. In the (multilayer) quantum dot layer according to an embodiment, the organic ligand content may decrease towards the electron auxiliary layer. In the quantum dot layer according to an embodiment, the halogen content may decrease toward the electron auxiliary layer. In the (multilayer) quantum dot layer according to an embodiment, the organic ligand content may increase towards the electron auxiliary layer.

A thickness of the first quantum dot layer may range from about 5 to about 35 nm, about 10 to about 30 nm, about 12 to about 25 nm, about 14 to about 23 nm, about 15 to about 20 nm, or a combination thereof. A thickness of the second quantum dot layer may range from about 3 to about 30 nm, about 7 to about 25 nm, about 10 to about 20 nm, or a combination thereof. The quantum dot layer (e.g., second quantum dot layer) may further include the inorganic nanoparticle.

If desired, the quantum dot layer formed (or treated with a halogen solution as described herein) may be washed with an organic solvent for washing (e.g., water or a water-miscible organic solvent). The washing method is not particularly limited and may be done by spin and dry, or immersion. In an embodiment, the washing may be omitted.

Optionally, the washed quantum dot layer may be subjected to heat treatment. The heat treatment may be performed in air or in an inert gas atmosphere, e.g., under nitrogen. The heat treatment may be performed at a temperature of greater than or equal to about 50° C., greater than or equal to about 70° C., greater than or equal to about 90° C., greater than or equal to about 100° C., greater than or equal to about 120° C., greater than or equal to about 150° C., greater than or equal to about 170° C., or greater than or equal to about 200° C. The heat treatment may be performed at a temperature of less than or equal to about 250° C., less than or equal to about 230° C., less than or equal to about 200° C., less than or equal to about 180° C., less than or equal to about 160° C., less than or equal to about 140° C., or less than or equal to about 130° C.

The electroluminescent device of an embodiment includes an electron transport layer based on zinc oxide nanoparticle disposed on the quantum dot layer, for example, between the second electrode and the quantum dot layer. The electron transport layer includes a plurality of zinc oxide nanoparticles. The electron auxiliary layer may include an electron transport layer. In an embodiment, a separate electron injection layer may be disposed between the second electrode and the electron transport layer but is not limited thereto. The electron transport layer may be disposed adjacent to the quantum dot layer (e.g., directly on the quantum dot layer). In an embodiment, the electron transport layer may contact the quantum dot layer.

The zinc oxide (nanoparticles) may include zinc; and optionally a Group IIA metal, Zr, W, Li, Ti, Y, Al, gallium, indium, tin (Sn), cobalt (Co), vanadium (V), or a combination thereof. The zinc oxide (nanoparticles) may include zinc, a Group IIA metal, and optionally, an alkali metal.

The zinc oxide (nanoparticle) may include a compound represented by Zn₁₋ₓ MₓO (wherein M is Mg, Ca, Zr, W, Li, Ti, Y, Al, or a combination thereof, 0≤x≤0.5). In the above chemical formula, x is a real number and may be greater than or equal to 0, e.g., greater than or equal to about 0.01, greater than or equal to about 0.03, greater than or equal to about 0.05, greater than or equal to about 0.07, greater than or equal to about 0.1, greater than or equal to about 0.13, greater than or equal to about 0.15, greater than or equal to about 0.17, greater than or equal to about 0.2, greater than or equal to about 0.23, or greater than or equal to about 0.25. The x may be less than or equal to about 0.47, less than or equal to about 0.45, less than or equal to about 0.43, less than or equal to about 0.4, less than or equal to about 0.37, less than or equal to about 0.35, less than or equal to about 0.3, or less than or equal to about 0.18.

The zinc oxide (nanoparticle) may further include magnesium. The electron auxiliary layer (or zinc oxide) may include Zn₁₋ₓMgₓO (x is greater than about 0 and less than or equal to about 0.5, e.g., x is as described above), ZnO, or a combination thereof. The zinc oxide may further include magnesium.

An average particle size of the metal oxide nanoparticle may be greater than or equal to about 1 nm, greater than or equal to about 2 nm, greater than or equal to about 2.5 nm, greater than or equal to about 3 nm, or greater than or equal to about 3.5 nm and less than or equal to about 10 nm, less than or equal to about 9 nm, less than or equal to about 8 nm, less than or equal to about 7 nm, less than or equal to about 6 nm, less than or equal to about 5 nm, or less than or equal to about 4.5 nm.

In an embodiment, the metal oxide nanoparticle (e.g., zinc oxide nanoparticle) may be prepared by an appropriate method and are not particularly limited. The preparation of metal oxide nanoparticle may include a sol-gel reaction. For example, zinc magnesium oxide nanoparticle may be prepared by adding a zinc compound (e.g., an organic zinc compound such as zinc acetate dihydrate) and an additional metal compound (e.g., an additional organic metal compound such as magnesium acetate tetrahydrate) to have a desired mole ratio in a reactor including an organic solvent (e.g. dimethyl sulfoxide), heating in air to a predetermined temperature (e.g., about 40 to about 120° C., or about 60° C. to about 100° C.), then adding a precipitation accelerator solution (e.g., an ethanol solution of tetramethylammonium hydroxide pentahydrate) dropwise thereto, and stirring the resultant. The prepared zinc oxide nanoparticle (e.g., ZnₓMg₁₋ₓO nanoparticle) may be separated from the reaction solution by centrifugation.

In an embodiment, the electron auxiliary layer may be provided through a solution process. In an embodiment, the electron auxiliary layer (e.g., electron transport layer) is formed by dispersing a plurality of metal oxide nanoparticles in an organic solvent (e.g., a polar organic solvent, a non-polar organic solvent, or a combination thereof) to obtain a precursor dispersion and applying the precursor dispersion to form a film. The electron auxiliary layer precursor dispersion may be applied on the quantum dot layer or the first layer. The solution process may further include removing the organic solvent (e.g., by evaporation, etc.) from the formed film. The organic solvent may be a C1 to C10 alcohol solvent or a combination thereof.

In an embodiment, the electron auxiliary layer 4 or 40 may further include an electron injection layer, a hole blocking layer, or a combination thereof. An electron injection layer may be disposed between the electron transport layer and the second electrode. In an embodiment, a hole blocking layer may be disposed between the light emitting layer and the electron transport layer. The thickness of the electron injection layer, the thickness of hole blocking layer, or a combination thereof are not particularly limited and may be selected appropriately. The thickness of the electron injection layer, hole blocking layer, or combination thereof may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about and 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

The electron injection layer and/or hole blocking layer material may be appropriately selected and is not particularly limited. In an embodiment, the electron injection layer and/or hole blocking layer material may include at least one selected from 1,4,5,8-naphthalene-tetracarboxylic dianhydride (NTCDA), bathocuproine (BCP), tris[3-(3-pyridyl)-mesityl]borane (3TPYMB), LiF Alq₃, Gaq₃, Inq₃, Znq₂, Zn(BTZ)₂, BeBqz, ET204(8-(4-(4,6-di(naphthalen-2-yl)-1,3,5-triazin-2-yl)phenyl)quinolone), 8-hydroxyquinolinato lithium (Liq), 2,2′,2″-(1,3,5-benzinetriyI)-tris(1-phenyl-1-H-benzimidazole) (TP Bi), n-type metal oxide (e.g., zinc oxide, HfO₂, etc.), 8-(4-(4,6-di(naphthalen-2-yl)-1,3,5-triazin-2-yl)phenyl)quinolone:8-hydroxyquinolinato lithium (ET204:Liq), and a combination thereof, but is not limited to thereto.

In the aforementioned electron transport layer, the metal oxide nanoparticles may provide higher electron mobility than organic semiconductor materials, and for example, the quantum dot layer may exhibit electroluminescence properties at a desired level by combining it with an electron transport layer based on metal oxide nanoparticle, as described below. Additionally, the quantum dot layer based on semiconductor nanoparticle may be formed through a solution process, and an electron transport layer based on metal oxide nanoparticle may be formed on the quantum dot layer through a solution process, which may be desirable in terms of process.

The luminescent device of an embodiment may be produced by a method including optionally forming a hole auxiliary layer on the first electrode; forming a first layer on the first electrode or on the hole auxiliary layer; forming the quantum dot layer on the first layer; forming the electron auxiliary layer on the quantum dot layer; and forming the second electrode on the electron auxiliary layer.

In an embodiment, the hole auxiliary layer may be formed, for example, by deposition or coating, depending on its material. Formation of the first layer, quantum dot layer, and electron auxiliary layer is as described above. The method of forming the second electrode is not particularly limited, and may be formed (e.g., by deposition or coating) depending on the electrode material.

An electroluminescent device of an embodiment may exhibit improved levels of electroluminescent properties (e.g., along with extended life-span). The luminescent device of an embodiment may be configured to emit red light, green light, or blue light.

The electroluminescent device of an embodiment may have a maximum external quantum efficiency (EQE) of greater than or equal to about 5%, greater than or equal to about 5.5%, greater than or equal to about 6%, greater than or equal to about 6.5%, greater than or equal to about 7%, greater than or equal to about 7.5%, greater than or equal to about 7.7%, greater than or equal to about 8%, greater than or equal to about 8.5%, greater than or equal to about 9%, greater than or equal to about 9.5%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%.

An electroluminescent device of an embodiment may have a maximum external quantum efficiency of less than or equal to about 100%, less than or equal to about 90%, less than or equal to about 80%, less than or equal to about 70%, less than or equal to about 60%, less than or equal to about 50%, less than or equal to about 40%, less than or equal to about 30%, or less than or equal to about 20%.

The luminescent device of an embodiment may have a maximum luminance of greater than or equal to about 10,000 candela per square meter (cd/m²), greater than or equal to about 20,000 cd/m², greater than or equal to about 30,000 cd/m², greater than or equal to about 40,000 cd/m², greater than or equal to about 50,000 cd/m², greater than or equal to about 60,000 cd/m², greater than or equal to about 65,000 cd/m², greater than or equal to about 70,000 cd/m², greater than or equal to about 80,000 cd/m², greater than or equal to about 90,000 cd/m², greater than or equal to about 95,000 cd/m², greater than or equal to about 100,000 cd/m², greater than or equal to about 110,000 cd/m², greater than or equal to about 120,000 cd/m², greater than or equal to about 130,000 cd/m², greater than or equal to about 140,000 cd/m², greater than or equal to about 150,000 cd/m², greater than or equal to about 160,000 cd/m², greater than or equal to about 170,000 cd/m², greater than or equal to about 180,000 cd/m², greater than or equal to about 190,000 cd/m², greater than or equal to about 200,000 cd/m², greater than or equal to about 210,000 cd/m², greater than or equal to about 220,000 cd/m², greater than or equal to about 230,000 cd/m², greater than or equal to about 240,000 cd/m², greater than or equal to about 250,000 cd/m², greater than or equal to about 300,000 cd/m², greater than or equal to about 400,000 cd/m², greater than or equal to about 500,000 cd/m², greater than or equal to about 600,000 cd/m², greater than or equal to about 700,000 cd/m², greater than or equal to about 800,000 cd/m², greater than or equal to about 900,000 cd/m², or greater than or equal to about 1,000,000 cd/m².

The luminescent device of an embodiment may have a maximum luminance of less than or equal to about 2,000,000 cd/m² (nit), less than or equal to about 1,500,000 cd/m², or less than or equal to about 1,000,000 cd/m².

The luminescent device of an embodiment may have (e.g., when driven at a predetermined initial luminance, for example, about 650 nits or 280 nits) T50 of greater than or equal to about 20 hours, for example, greater than or equal to about 25 hours, greater than or equal to about 30 hours, greater than or equal to about 40 hours, greater than or equal to about 50 hours, greater than or equal to about 60 hours, greater than or equal to about 65 hours, greater than or equal to about 70 hours, greater than or equal to about 80 hours, greater than or equal to about 90 hours, greater than or equal to about 100 hours, greater than or equal to about 120 hours, greater than or equal to about 150 hours, greater than or equal to about 180 hours, greater than or equal to about 200 hours, or greater than or equal to about 250 hours. The T50 may range from about 25 hours to about 1000 hours, about 130 hours to about 500 hours, about 190 hours to about 300 hours, or a combination thereof.

The luminescent device may have T90 (when driven at a predetermined initial luminance, for example, 650 nits) of greater than or equal to about 5 hours, greater than or equal to about 6 hours, greater than or equal to about 7 hours, greater than or equal to about 7.5 hours, greater than or equal to about 8 hours, greater than about 8.3 hours, greater than or equal to about 9 hours, greater than or equal to about 9.9 hours, greater than or equal to about 10 hours, greater than or equal to about 20 hours, greater than or equal to about 25 hours, greater than or equal to about 30 hours, greater than or equal to about 34 hours, greater than or equal to about 40 hours, greater than or equal to about 50 hours, greater than or equal to about 60 hours, greater than or equal to about 70 hours, greater than or equal to about 80 hours, greater than or equal to about 90 hours, greater than or equal to about 100 hours, greater than or equal to about 110 hours, greater than or equal to about 120 hours, or greater than or equal to about 130 hours. The electroluminescent device (when driven at a predetermined initial luminance, for example, 650 nits) has T90 of about 35 hours to about 1500 hours, about 55 hours to about 1200 hours, about 85 hours to about 1000 hours, about 105 hours to about 900 hours, about 115 hours to about 800 hours, about 145 hours to about 500 hours, or a combination thereof.

Another embodiment relates to a display device (e.g., display panel) including a luminescent device according to an embodiment.

The display device (e.g., display panel) may include a first pixel and a second pixel configured to emit light of a different color from the first pixel.

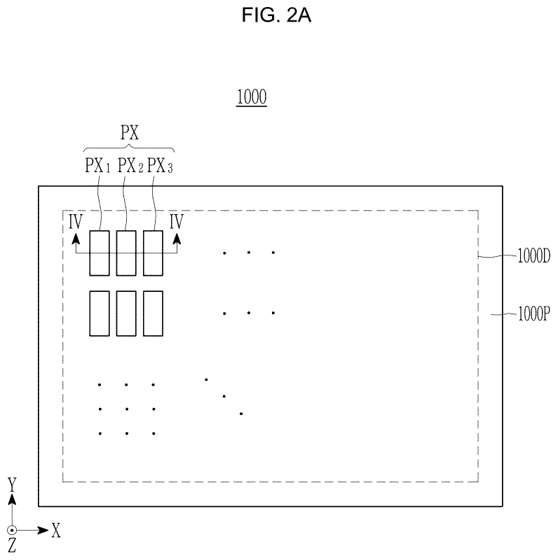

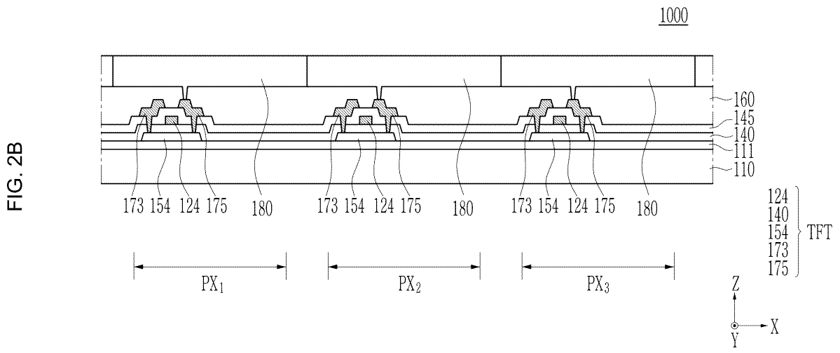

Referring to FIG. 2A, the display panel 1000 according to an embodiment may include a display area 1000D for displaying an image, and optionally, a non-display area 1000P disposed around the display area 1000D and where the binder is disposed. The display area 1000D may include a plurality of pixels PXs arranged along a row (e.g., X direction) and/or a column (e.g., Y direction), and each pixel PX may include a plurality of sub-pixels PX₁, PX₂, and PX₃ displaying different colors. Herein, as an example, a configuration in which three sub-pixels PX₁, PX₂, and PX₃ constitute one pixel PX is illustrated, but the configuration is not limited thereto. An additional sub-pixel such as a white sub-pixel may be further included, and one or more sub-pixel displaying the same color may be included. The plurality of pixels PXs may be arranged in, for example, a Bayer matrix, a PenTile matrix, and/or a diamond matrix, but is not limited thereto.

Each of the sub-pixels PX₁, PX₂, and PX₃ may be configured to display a color of three primary colors or a combination of three primary colors, for example, red, green, blue, or a combination thereof. For example, the first sub-pixel PX₁ may be configured to display red, the second sub-pixel PX₂ may be configured to display green, and the third sub-pixel PX₃ may be configured to display blue.

In the drawing, an example in which all sub-pixels have the same size is illustrated, but the present disclosure is not limited thereto. At least one of the sub-pixels may be larger or smaller than the other sub-pixels. In the drawing, an example in which all sub-pixels have the same shape is illustrated, but the present disclosure is not limited thereto. At least one of the sub-pixels may have a different shape from other sub-pixels.

In reference to FIG. 2B, in an embodiment, the display panel 1000 may include a substrate 110, a buffer layer 111, a thin film transistor TFT, and a luminescent device 180. The display panel 1000 may include circuit elements configured to switch and/or drive each luminescent device.

Referring to FIG. 2B, the luminescent devices 180 may be arranged in each sub-pixel PX₁, PX₂, and PX₃, and the luminescent devices 180 arranged in the sub-pixels PX₁, PX₂, and PX₃ may each independently be driven. The sub-pixel may include a blue sub-pixel, a red sub-pixel, or a green sub-pixel. At least one of the luminescent devices 180 may be an electroluminescence device according to an embodiment.

The substrate 110 is as described above. The buffer layer 111 may include an organic material, an inorganic material, or an organic-inorganic material, and may include, for example, an oxide, a nitride, or an oxynitride, for example, silicon oxide, silicon nitride, silicon oxynitride, or a combination thereof, but is not limited thereto. The buffer layer 111 may be one layer or two or more layers, and may cover the whole surface of the lower substrate 110. The buffer layer 111 may be omitted.

The thin film transistor TFT may be a three-terminal element for switching and/or driving the light emitting device 180 and one or two or more may be included for each sub-pixel. The thin film transistor TFT includes a gate electrode 124, a semiconductor layer 154 overlapped with the gate electrode 124, a gate insulating film 140 between the gate electrode 124 and the semiconductor layer 154, and a source electrode 173 and a drain electrode 175 electrically connected to the semiconductor layer 154. In the drawings, a coplanar top gate structure is shown as an example, but the present disclosure is not limited to the structure and may have various structures. The gate electrode 124 is electrically connected to a gate line (not shown), and may include, for example, a low-resistance metal such as aluminum (Al), molybdenum (Mo), copper (Cu), titanium (Ti), silver (Ag), gold (Au), an alloy thereof, or a combination thereof, but is not limited thereto.

The semiconductor layer 154 may be an inorganic semiconductor such as amorphous silicon, polycrystalline silicon, or an oxide semiconductor; an organic semiconductor; an organic-inorganic semiconductor; or a combination thereof. For example, the semiconductor layer 154 may include an oxide semiconductor including at least one of indium (In), zinc (Zn), tin (Sn), and gallium (Ga), and the oxide semiconductor may include, for example, indium-gallium-zinc oxide, zinc-tin oxide, or a combination thereof, but is not limited thereto. The semiconductor layer 154 may include a channel region and doped regions that are disposed on both sides of the channel region and are electrically connected to the source electrode 173 and the drain electrode 175, respectively.

The gate insulating film 140 may include an organic material, an inorganic material, or an organic-inorganic material, and may include, for example, an oxide, a nitride, or an oxynitride, for example, silicon oxide, silicon nitride, silicon oxynitride, or a combination thereof, but is not limited thereto. In the drawing, an example in which the gate insulating film 140 is formed on the whole surface of the lower substrate 110 is illustrated, but the present disclosure is not limited thereto, and may be selectively formed between the gate electrode 124 and the semiconductor layer 154. The gate insulating film 140 may be one or two or more layers.

The source electrode 173 and the drain electrode 175 may include a low-resistance metal such as aluminum (Al), molybdenum (Mo), copper (Cu), titanium (Ti), silver (Ag), gold (Au), an alloy thereof, or a combination thereof, but is not limited thereto. Each of the source electrode 173 and the drain electrode 175 may be electrically connected to a doped region of the semiconductor layer 154. The source electrode 173 is electrically connected to a data line (not shown), and the drain electrode 175 is electrically connected to a light emitting device 180 to be described later.

An interlayer insulating film 145 may be additionally formed between the gate electrode 124 and the source/drain electrodes 173 and 175. The interlayer insulating film 145 may include an organic material, an inorganic material, or an organic-inorganic material, and may include, for example, an oxide, a nitride, or an oxynitride, for example, silicon oxide, silicon nitride, silicon oxynitride, or a combination thereof, but is not limited thereto. The interlayer insulating film 145 may be one layer or two or more layers.

In an embodiment, a protective film 160 may be formed on the thin film transistor TFT. The protective film 160 may be, for example, a passivation film, but is not limited thereto. The protective film 160 may include an organic material, an inorganic material, or an organic-inorganic material, and may include, for example, polyacryl, polyimide, polyamide, polyamideimide, or a combination thereof, but is not limited thereto. The protective film 160 may be one layer or two or more layers.

In an embodiment, one of the first electrodes 1 and 10 and the second electrode 5 or 50 may be a pixel electrode connected to the TFT, and the other may be a common electrode.

The display device of an embodiment may be used as a top emission type display panel, a bottom emission type display panel, or a both side emission type display panel.

In an embodiment, the first electrodes 1 and 10 may be a light-transmitting electrode and the second electrode 5 and 50 may be a reflecting electrode, and the display panel may be a bottom emission type display panel that emits light toward the first electrodes 1 and 10 and, if present, toward the substrate 110. In an embodiment, the first electrodes 1 and 10 may be reflecting electrodes and the second electrode 5 and 50 may be a light-transmitting electrode, and the display panel may be a top emission type display panel that emits light to the opposite side of the first electrodes 1 and 10 and, if present, the substrate 110. In an embodiment, both the first electrode and the second electrode may be light-transmitting electrodes, and the display panel 1000 may be a both side emission type display panel that emits light to a side of the substrate 110 and to a side opposite to the substrate 110.

The display device may include a portable terminal device, a monitor, a notebook computer, a television, an electric sign board, a camera, or an electronic component (for example, for an electric vehicle).

Specific examples are described below. However, the examples described below are only for specifically illustrating or explaining the disclosure, and the scope of the disclosure is not limited thereto.

### EXAMPLES

### Analysis Method

### [1] Electroluminescence Spectroscopic Analysis

A current according to a voltage is measured with a Keithley 2635B source meter as voltage is applied, and EL emission luminance is measured using a CS2000 spectroradiometer to measure electroluminescence properties.

### [2] Life-Span Characteristics

T90 and T50 are measured with an initial luminance of 650 nit (candelas per square meter (cd/m²)). For the measurement of T90, a device is operated with a current value corresponding to a predetermined luminance (e.g., 650 nit) measured with a spectral luminance meter. The light emitted from the device is converted into a photocurrent corresponding to the predetermined luminance through a photo-diode, and based on the initial photocurrent value 100%, the time (hours (hr)) taken to become 90% of the initially measured photocurrent value is measured and determined. For the measurement of T50, a device is operated with a current value corresponding to a predetermined luminance (e.g., 650 nit) measured with a spectral luminance meter. The light emitted from the device is converted into a photocurrent corresponding to the predetermined luminance through a photo-diode, and based on the initial photocurrent value 100%, the time (hr) taken to become 50% of the initially measured photocurrent value is measured and determined.

### [3] HOMO Energy Level Measurement and UV-Vis Absorption Spectrum (Bandgap Measurement)

(1) The HOMO level is measured by using a surface analyzer (Model AC-3, photoelectron spectrophotometer in Air) of Riken Keiki Co. Ltd.

(2) A UV spectroscopic analysis is performed by obtaining a UV-Visible absorption spectrum with an Agilent Cary5000 spectrometer. The (optical) bandgap energy may be obtained from a wavelength where light absorption starts in the UV-Vis absorption spectrum. For example, if the UV absorption starts at 325 nm, the energy bandgap is 1240/325=3.81 eV.

### [4] TEM Analysis

A UT F30 Tecnai electron microscope may be used to obtain transmission electron micrographs of the prepared nanocrystals. From the obtained transmission electron micrographs, an average particle size of the nanocrystals is obtained by using Image J.

The following synthesis is performed under an inert gas atmosphere (i.e., under a nitrogen or under a flow of nitrogen), unless otherwise specified. A precursor content is a mole content unless otherwise specified.

### Synthesis Example 1

A 2M Se/TOP stock solution, a 1M S/TOP stock solution, and a 0.1M Te/TOP stock solution are prepared by dispersing selenium (Se), sulfur (S), and tellurium (Te) in trioctylphosphine (TOP), respectively. To a reactor containing trioctylamine, 0.125 millimole (mmol) of zinc acetate and oleic acid is added and heated at 120° C. under vacuum. After 1 hour nitrogen is added to the reactor.

The reactor is heated to 300° C., the Se/TOP stock solution and the Te/TOP stock solution in a Te/Se ratio of 1/20 are rapidly injected into the reactor. Upon completion of the reaction, the reactor (reaction product) is rapidly cooled to room temperature, and acetone is added to facilitate formation of a precipitate. The resulting precipitate is separated with a centrifuge, and the precipitate is dispersed in toluene to obtain a ZnSeTe core dispersed in toluene.

1.8 mmol of zinc acetate with oleic acid is added to a flask containing trioctylamine and vacuum-treated at 120° C. for 10 minutes. Nitrogen is added to the flask and the flask is heated to 180° C. The above-prepared ZnTeSe core is added to the flask followed by the injection of Se/TOP and S/TOP stock solutions. The reaction temperature is set at about 280° C. Upon completion of the reaction the reactor is cooled to room temperature and the resulting nanocrystals are separated with a centrifuge and washed with ethanol. The nanocrystals are dispersed in toluene to obtain blue light emitting semiconductor nanoparticles.

A photoluminescence (PL) spectroscopic analysis of the blue light emitting semiconductor nanoparticles is performed using a Hitachi F-7000 spectrophotometer. The PL analysis confirms that the semiconductor nanoparticles have a peak emission wavelength of 455 nm.

### Synthesis Example 2: Synthesis of ZnMgO Nanoparticles

Zinc acetate dihydrate and magnesium acetate tetrahydrate are added to a reactor containing dimethylsulfoxide and heated at 60° C. in air. Subsequently, an ethanol solution of tetramethylammonium hydroxide pentahydrate is added to the reactor. After stirring the mixture for 1 hour, a precipitate form and is separated from the reaction mixture with a centrifuge. The precipitate is dispersed in ethanol to obtain Zn₁₋ₓMgₓO nanoparticles. (x=0.15)

The obtained nanoparticles are subjected to a transmission electron microscope analysis. The particles have an average size of about 3 nm.

### Synthesis Example 3: ZnS Nanoparticle Synthesis and Surface Treatment

[1] Sulfur is dispersed in trioctylphosphine (TOP) to obtain a 1 M S/TOP stock solution. In a 300 mL reaction flask, zinc acetate along with oleic acid is dissolved in trioctylamine and heated at 120° C. under vacuum. After 1 hour, nitrogen is added to the reaction flask, and the flask heated to 300° C. The prepared S/TOP stock solution is then quickly injected into the reaction flask. After 60 minutes, the reaction solution is cooled to room temperature, ethanol is added to facilitate formation of a precipitate, and the precipitate is separated by centrifugation. The precipitate is dispersed in hexane to obtain ZnS nanoparticles. The Zn and S precursors are used (added) at a mole ratio of Zn:S of 2:1.

The prepared ZnS nanoparticles have a particle size of about 5.61+/−0.7 nm.

### [2] Surface Treatment (Ligand Exchange):

The ZnS nanoparticles are dispersed in hexane and mercaptopropionic acid (MPA) is then added, and then 2× volume of ethanol is added. The resulting transparent solution is stirred at 80° C.

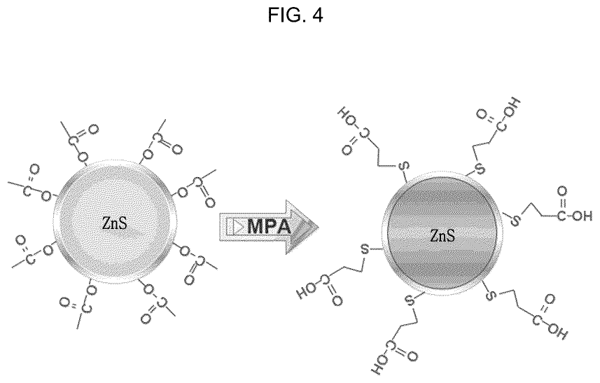

As schematically represented in FIG. 4, the mercaptopropionic acid is involved in a surface ligand exchange of the ZnS nanoparticles, which are also believed to be coated with a (water-soluble) thiolate compound. After the exchange reaction, ethyl acetate is added to the solution of ZnS nanoparticles, and then the nanoparticles are separated by centrifugation. The obtained powder is in the form of a colloid dispersion if dispersed in ethanol. (a DLS particle size: 5 to 10 nm)

### Experimental Example 1

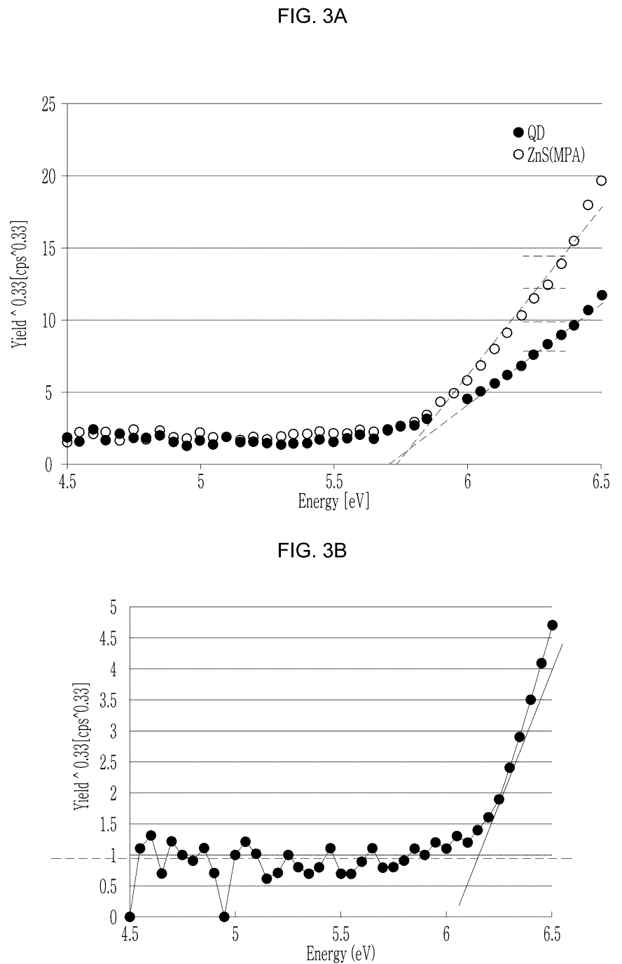

The ZnS nanoparticles before and after the ligand (surface) exchange of Synthesis Example 3, and the quantum dots are measured with respect to a HOMO level by using AC3 (see, analysis [3](1)), and the results are shown in FIGS. 3A and 3B and Table 2.

TABLE 2

| | AC3 HOMO |
|---|---|
| | energy level |
| | (eV) |
| Quantum dots | 5.75 |
| ZnS (MPA treated) | 5.78 |
| ZnS prior to | 6.18 |
| surface treated | |

The surface-treated ZnS nanoparticle of Synthesis Example 3 exhibit a smaller HOMO energy level difference from the quantum dot, than the ZnS nanoparticle prior to the surface treatment.

### Experimental Example 2

The ZnS nanoparticles before and after the ligand exchange (surface treatment) of Synthesis Example 3 are subject to a UV-Vis absorption spectroscopy analysis. The surface-treated ZnS nanoparticles are also subject to a PL spectroscopic analysis. The results are shown in Table 3.

TABLE 3

| | UV peak (nm) |
|---|---|
| ZnS before | 309 |
| surface-treatment | |
| ZnS after | 308 |
| surface-treatment | |

The surface exchanged ZnS exhibits a UV absorption that begins at about 325 nm to 330 nm and a bandgap energy of about 3.7 eV. Therefore, the surface exchanged ZnS has a LUMO of about 2.0 eV (=5.7 eV-3.7 eV) and a difference between the LUMO of the first layer and the LUMO of the QD layer is about 1.05 eV (=3.05-2.0). Moreover, the surface exchanged ZnS nanoparticles exhibit a PL peak at 400 nm upon irradiation with light at 280 nm.

### Example 1

The ZnS nanoparticles according to Synthesis Example 3 are dispersed in ethanol to obtain a dispersion for forming a first layer. The quantum dots as synthesized in Synthesis Example 1 are dispersed in octane to prepare a dispersion for forming a quantum dot layer.

On a silicon substrate, a 25 nm-thick organic-based hole transport layer (TFB or HTL1) is formed. On the hole transport layer, the dispersion for forming a first layer is spin-coated to form a first layer having a thickness of about 7 nm. The first layer is then heat-treated at 80° C. under an N₂ atmosphere for 30 minutes.

The dispersion for forming a quantum dot layer is spin-coated on the formed first layer to form a quantum dot layer with a target thickness of 28 nm. The formed quantum dot layer is heat-treated at 80° C. under a N₂ atmosphere for 30 minutes.

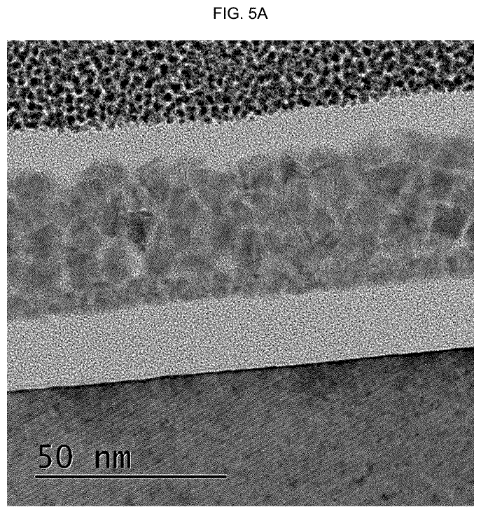

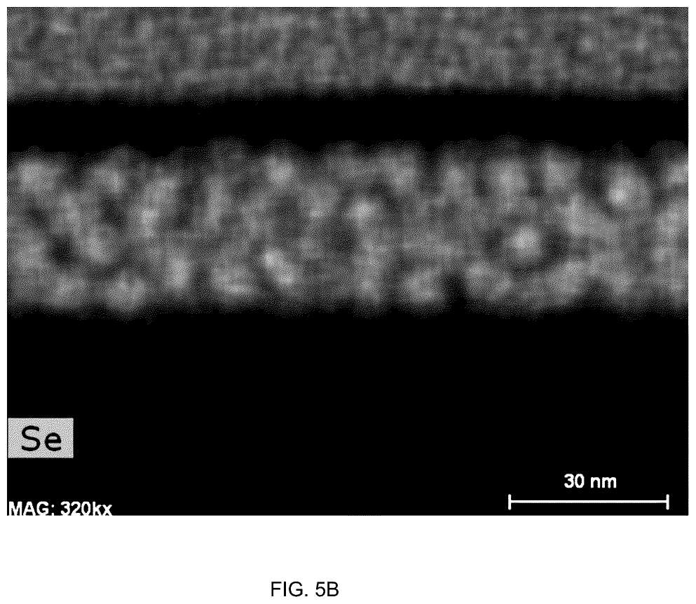

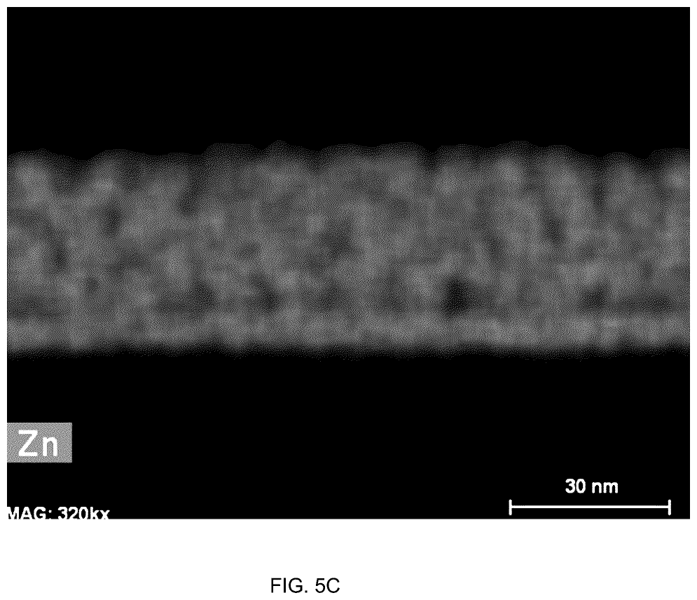

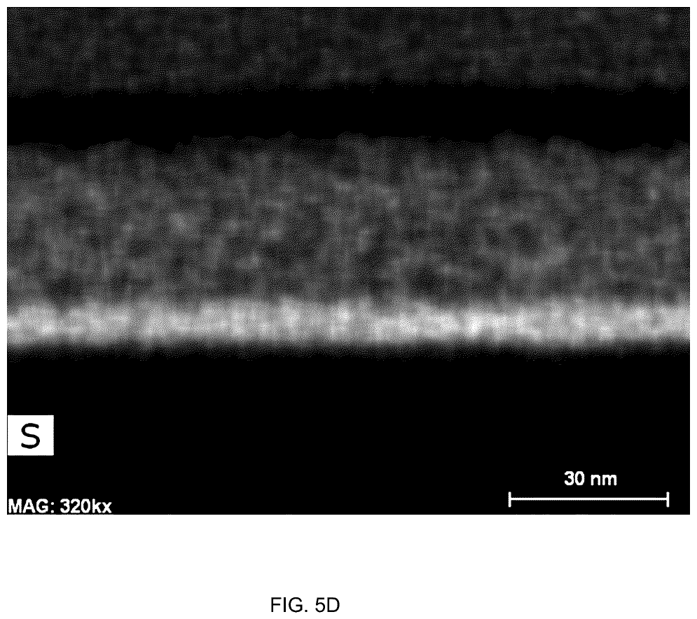

A TEM analysis and a TEM-EDX analysis are performed on a cross-section of the obtained layered structure, and the results are shown in FIGS. 5A, 5B, 5C, and 5D.

Referring to the obtained results, the first layer and the quantum dot layer are well formed on the organic-based hole transport layer.

### Device Manufacture

### Example 2

The zinc magnesium oxide nanoparticles prepared in Synthesis Example 2 are dispersed in ethanol to prepare an ETL dispersion. The ZnS (MPA) nanoparticles prepared in Synthesis Example 3 are dispersed in ethanol to prepare a dispersion for forming a first layer. The quantum dots synthesized in Synthesis Example 1 are dispersed in octane to prepare a dispersion for forming a quantum dot layer.

A glass substrate is surface-treated with UV-ozone for 15 minutes, and then ITO (first electrode) is deposited on the substrate. A PEDOT:PSS solution (H. C. Starks) is spin-coated on the ITO, heat-treated at 150° C. under an air for 10 minutes, and then heat-treated at 150° C. for 20 to 30 minutes under nitrogen to form a 30 nm-thick hole injection layer (HIL).

On the hole injection layer (HIL), a poly[(9,9-dioctylfluoren-2,7-diyl-co-(4,4′-(N-4-butylphenyl)diphenylamine] solution (TFB) (Sumitomo Corp.) is spin-coated and heat-treated at 180° C. for 30 minutes to form a 25 nm-thick hole transport layer.

On the obtained hole transport layer, the dispersion for forming a first layer is spin-coated and heat-treated at 80° C. for 30 minutes under nitrogen to form a 5 nm-thick first layer. On the first layer, the dispersion for forming a quantum dot layer is spin-coated and heat-treated at 80° C. for 30 minutes under nitrogen to form a quantum dot layer having a target thickness of 28 nm.

On the formed quantum dot layer, the dispersion for the ETL is spin-coated and heat-treated at 80° C. to form an electron auxiliary layer (thickness: 20 nm).

On the obtained electron auxiliary layer, aluminum (Al) is vacuum-deposited to form a 100 nm-thick second electrode to obtain a luminescent device.

The electro-luminescence properties of the luminescent device are measured and the results are listed in Table 4.

### Example 3: Manufacture of Device

An electroluminescent device is manufactured in the same manner as in Example 2 except that the thickness of the first layer is changed into 10 nm. The electro-luminescence properties of the luminescent device are measured and the results are listed in Table 4.

### Comparative Example 1

An electroluminescent device is manufactured in the same manner as in Example 2 except that the first layer is not formed. The electro-luminescence properties of the comparative luminescent device are measured and the results are listed in Table 4.

TABLE 4

| | EQE | Relative life-span |
|---|---|---|
| | (max) | (T90 (hour) driven |
| | % | at 650 nits) |
| Example 2 (ZnS 5) | 13.5 | 295% |
| Example 3 (ZnS 10) | 12.4 | 452% |
| Comparative Example 1 | 11.4 | 100% |

nit: cd/m²

Referring to the results of Table 4, the devices of Examples 2 and 3 each exhibit a relatively long life-span as well as improved EQE as compared to the device of the comparative example 1.

### Example 4

An electroluminescent device is manufactured in the same manner as in Example 2 except that the hole transport layer is formed by using an organic compound (HTL1, a fluorene aryl amine compound) having a HOMO energy level and a LUMO energy level of about 5.5 eV and about 2.68 eV, respectively. The electro-luminescence properties of the luminescent device are measured and the results are listed in Table 5.

### Comparative Example 2

An electroluminescent device is produced in the same manner as in Example 2 except that the hole transport layer is formed by using the organic compound having a HOMO energy level and a LUMO energy level of about 5.5 eV and about 2.68 eV, respectively, and the first layer is not present in the device. The electro-luminescence properties of the luminescent device are measured and the results are listed in Table 5.

TABLE 5

| | EQE | Relative life-span |
|---|---|---|
| | (max) | (T90 (hour) |
| | % | at 650 nits) |
| Example 4 | 11% | 120% |
| Comparative Example 2 | 8.8% | 100% |

nit: cd/m²

Referring to the results of Table 5, the device of Example 4 exhibits a longer life-span as well as improved EQE compared to the device of Comparative Example 2.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. An electroluminescent device comprising:
a first electrode and a second electrode;
a quantum dot layer between the first electrode and the second electrode; and optionally, an electron transport layer between the quantum dot layer and the second electrode, wherein the quantum dot layer comprises a quantum dot and is configured to emit first light,
wherein the electroluminescent device further comprises a first layer comprising an inorganic nanoparticle, the first layer disposed between the quantum dot layer and the first electrode,
wherein the inorganic nanoparticle comprises a metal chalcogenide comprising a Group II metal and a chalcogen element, and
the inorganic nanoparticle has a size of greater than or equal to about 0.5 nanometers and less than or equal to about 30 nanometers.

2. The electroluminescent device of claim 1, wherein
the electron transport layer comprises a zinc oxide nanoparticle.

3. The electroluminescent device of claim 1, wherein
the quantum dot comprises a Group II-VI compound, a Group III-V compound, a Group IV-VI compound, a Group IV element or compound, a Group II-III-VI compound, a Group I-III-VI compound, a Group I-II-IV-VI compound, or a combination thereof, and
wherein the first light represents a red light spectrum, a green light spectrum, a blue light spectrum, or a combination thereof, and a full width at half maximum of the emission peak of the first light is greater than or equal to about 1 nanometer and less than or equal to about 55 nanometers.

4. The electroluminescent device of claim 1, wherein
the Group II metal comprises a metal comprising zinc, magnesium, calcium, barium, strontium, or a combination thereof, and
the chalcogen element comprises selenium, sulfur, tellurium, or a combination thereof.

5. The electroluminescent device of claim 1, wherein
the metal chalcogenide comprises a magnesium sulfide, a magnesium selenide, a magnesium sulfide selenide, a zinc magnesium selenide, a zinc magnesium sulfide, a zinc sulfide, a zinc selenide sulfide, a barium sulfide, a barium selenide, a barium sulfide selenide, a calcium sulfide, a calcium selenide, a calcium selenide sulfide, or a combination thereof.

6. The electroluminescent device of claim 1, wherein
a bandgap energy of the metal chalcogenide is greater than or equal to about 3.0 eV and less than or equal to about 6 eV.

7. The electroluminescent device of claim 1, wherein
a difference between a LUMO energy level of the metal chalcogenide and a LUMO energy level of the quantum dot layer is greater than or equal to about 0.3 eV.

8. The electroluminescent device of claim 1, wherein
the first layer further comprises an organic moiety, and
a mole ratio of carbon to the Group II metal in the first layer is greater than or equal to about 0.001:1 and less than or equal to about 1:1.

9. The electroluminescent device of claim 1, wherein
the inorganic nanoparticle has a particle size of greater than or equal to about 1 nanometer and less than or equal to about 10 nanometers.

10. The electroluminescent device of claim 1, wherein
the inorganic nanoparticle further comprises an organic ligand on a surface of the inorganic nanoparticle, and
the organic ligand is represented by Chemical Formula 1:
A-L-B Chemical Formula 1
wherein L is a single bond, a substituted or unsubstituted C1 to C50 aliphatic hydrocarbon group, a substituted or unsubstituted C4 to C50 aromatic hydrocarbon group, or a combination thereof, and
A and B are each independently a thiol group, a carboxyl group, a hydroxy group, an amine group, a phosphonic acid group, a phosphoric acid group, a phosphinic acid group, or a moiety derived therefrom.

11. The electroluminescent device of claim 1, wherein
the inorganic nanoparticle is configured to be dispersible in water or a water-miscible organic solvent.

12. The electroluminescent device of claim 10, wherein
the organic ligand comprises a diacid compound, a mercapto carboxylic acid compound, a mercapto amine compound, a mercapto phosphonic acid compound, a mercapto phosphoric acid compound, a mercapto phosphinic acid compound, a hydroxy carboxylic acid compound, a hydroxy amine compound, a hydroxy phosphonic acid compound, a hydroxy phosphoric acid compound, a hydroxy phosphinic acid compound, or a combination thereof.

13. The electroluminescent device of claim 1, further comprising a hole transport layer between the first electrode and the first layer.

14. The electroluminescent device of claim 13, wherein
the hole transport layer comprises a hole transporting organic compound, and
the hole transporting organic compound comprising a substituted or unsubstituted fluorenyl moiety, a substituted or unsubstituted diphenylamine moiety, a triphenylamine moiety, or a combination of thereof.

15. The electroluminescent device of claim 13, wherein
a LUMO level of the metal chalcogenide is shallower than a LUMO level of the hole transport layer, and
a bandgap energy of the metal chalcogenide is greater than a bandgap energy of the hole transport layer.

16. The electroluminescent device of claim 13, further comprising a hole injection layer between the first electrode and the hole transport layer, and
the hole injection layer comprises an organic compound different from the hole transport layer, a hole transporting inorganic material, or a combination thereof.

17. The electroluminescent device of claim 1, wherein
the first layer has a thickness of greater than or equal to about 4 nanometers and less than or equal to about 15 nanometers, and optionally wherein the quantum dot layer has a thickness of greater than or equal to about 5 nanometers and less than or equal to about 50 nanometers.

18. The electroluminescent device of claim 1, wherein
the first light is blue light; and
wherein the electroluminescent device has a maximum luminance of greater than or equal to about 100,000 candela per square meter, or
wherein the electroluminescent device has a maximum external quantum efficiency of greater than or equal to about 11%,
or a combination thereof.

19. A display device comprising the electroluminescent device of claim 1.

20. The display device of claim 19, wherein
the display device comprises a portable terminal device, a monitor, a notebook computer, a television, an electric sign board, a camera, or an electronic component for an electric vehicle.
